(19) United States
(12) Patent Application Publication
(10) Pub. No.: US 2010/0203450 A1
(43) Pub. Date: Aug. 12, 2010

(54) PHOTORESIST COMPOSITIONS AND METHODS OF USE

(75) Inventors: Masaki Fujiwara, Cupertino, CA (US); Hiroshi Ito, San Jose, CA (US); Kazuhiro Yamanaka, San Jose, CA (US)

Correspondence Address: CANTOR COLBURN, LLP - IBM ARC DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 12/369,150

(22) Filed: Feb. 11, 2009

(51) Int. Cl. G03F 7/004; G03F 7/20

(52) U.S. Cl. 430/285.1; 430/286.1; 430/326; 430/323

(57) ABSTRACT

A photoresist composition comprises a polymer capable of radiation induced main chain scission and acid-catalyzed deprotection, wherein the polymer is derived by free radical polymerization of two or more monomers, each having an alpha-substituent on a polymerizable vinyl group; and a photochemical acid generator.

### BACKGROUND

The present disclosure is generally related to photoresist compositions and methods of their use.

Photoresist films are used for transferring an image formed therein to an underlying layer or substrate. A layer of a photoresist material is formed over a substrate to which the image is to be transferred. The photoresist layer is then exposed through a photomask to a source of activating radiation where the photomask has some areas that are opaque to such radiation and other areas that are transparent. A photoinduced chemical transformation results in the areas exposed to the activating radiation which allows for the development of a relief image therein.

Photoresists can be either positive-working or negative-working. Generally, negative-working photoresists undergo a crosslinking reaction within those portions of the photoresist layer that are exposed to activating radiation. As a result, the exposed portions become less soluble than unexposed portions in a solution used to develop the relief image. In contrast, positive-working photoresists become more soluble in a developer solution in the exposed areas of the photoresist layer compared to areas unexposed to such radiation.

Chemical amplification resists are used to increase the sensitivity to the exposure energy. In one method of chemical amplification, the exposure causes the release of an acid from a photochemical acid generator (PAG) component. The acid diffuses during a post-exposure bake step to react with acid labile groups of the polymeric resist material, thus deprotecting the groups to form more soluble chains in developer (positive-working). A single acid molecule can catalyze many such deprotection reactions; hence, amplification for a given exposure. Chemical amplification resists offer high sensitivity and high contrast but their resolution capability below 30 nm is questionable and large line edge roughness (LER) is a concern.

Electron beam (e-beam) polymeric resists are also positive-working. High energy e-beam exposures cause the resist polymers to fragment by main chain scission. The fragmented chains have greater developer solubility than the unexposed resist. E-beam lithography is becoming critically important in photomask and imprint template fabrication. Poly(methyl methacrylate) (PMMA) and ZEP (a copolymer of methyl alpha-chloroacrylate and alpha-methylstyrene) are solvent-developed high resolution electron beam resists that offer good LER, but their sensitivity is too low for high volume manufacturing.

Thus, a need exists to improve the sensitivity of e-beam resists, maintaining high resolution and low LER.

### BRIEF SUMMARY

Accordingly, embodiments of this disclosure address these and other needs.

In one embodiment a photoresist composition comprises a polymer capable of radiation induced main chain scission and acid-catalyzed deprotection, wherein the polymer is derived by free radical polymerization of two or more monomers, each having an alpha-substituent on a polymerizable vinyl group; and a photochemical acid generator.

In another embodiment a method of forming a relief image comprises disposing on a substrate a layer comprising a polymer capable of radiation induced main chain scission and acid-catalyzed deprotection, wherein the polymer is derived by free radical polymerization of two or more monomers, each having an alpha-substituent on a polymerizable vinyl group; and a photo-acid generator; imagewise irradiating the layer to form fragmented chains of the polymer in an irradiated area; heating the layer to effect acid-catalyzed deprotection of the fragmented chains of polymer in the irradiated area; and developing the layer with a developer to form the relief image disposed on the substrate.

Other systems, methods, features, and advantages of the present photoresist compositions will be or become apparent to one with skill in the art upon examination of the following drawings and detailed description. It is intended that all such additional systems, methods, features, and advantages be included within this description, be within the scope of the current disclosure, and be protected by the accompanying claims.

### BRIEF DESCRIPTION OF THE SEVERAL VIEWS OF THE DRAWINGS

FIG. 1 is a schematic comparing prior) art resist materials to the disclosed polymers capable of main chain scission and chemical amplification.

FIG. 2 is a graph of the GPC curves of unexposed and exposed (1.5 J/cm² of 254 nm radiation) copolymer, TBMA-TFMEST 83/17 (mol/mol) of Example 1.

FIG. 3 is a graph of the GPC curves of unexposed and exposed (1.5 J/cm² of 254 nm radiation) copolymer, TBTFMA-MEST 48/52 (mol/mol) of Example 20.

FIG. 4 is a graph of the GPC curves of unexposed and exposed (1.5 J/cm² of 254 nm radiation) copolymer, TBMA-MEST 57/43 (mol/mol) of Example 3.

FIG. 5 is a graph of the dissolution kinetics curves of TBTFMA-MMA 35/65 (mol/mol) of Example 12 after exposure to 254 nm radiation, and post-exposure bake.

FIG. 6 is a graph of the dissolution kinetics curves of TBFA-MEST 47/53 (mol/mol) of Example 5 after exposure to 254 nm radiation, and post-exposure bake.

FIG. 7 is a graph of the dissolution kinetics curves of TBFA-FMA 35/65 (mol/mol) of Example 16 after exposure to 254 nm radiation, and post-exposure bake.

FIG. 8 is a graph of the dissolution kinetics curves of TBFA-MMA 35/65 (mol/mol) of Example 14 after exposure to 254 nm radiation, and post-exposure bake.

FIG. 9 is a graph of the dissolution kinetics curves of TBMA-MFA 32/68 of Example 19 after exposure to 254 nm radiation, and post-exposure bake.

FIG. 10 is a graph of the contrast curves for a photoresist composition made with TBFA-MEIN 39/61 (mol/mol) of Example 6, after e-beam (100 keV) exposure, post-exposure bake, and development.

FIG. 11 is a graph of the contrast curves of a photoresist composition made with TBFA-MEST 47/53 (mol/mol) of Example 5, after e-beam (100 keV) exposure, post-exposure bake, and development

FIG. 12 is a graph of the contrast curves of a photoresist composition made with TBTFMA-MMA 35/65 (mol/mol) of Example 12, after e-beam (100 keV) exposure, post-exposure bake, and development

FIG. 13 is a graph of the contrast curves of a photoresist composition made with TBTFMA-MFA 29/71 (mol/mol) of Example 21, after e-beam (100 keV) exposure, post-exposure bake, and development

FIG. 14 is a scanning electron micrograph of 50 nm line/space patterns delineated in a photoresist composition made with TBTFMA-MMA 35/65 (mol/mol) of Example 12 by 400 microCoulombs/cm² of e-beam (100 keV) exposure, post-exposure bake, and development with isopropanol.

The disclosure may be understood more readily by reference to the following detailed description of the various features of the disclosure and the examples included therein.

### DETAILED DESCRIPTION

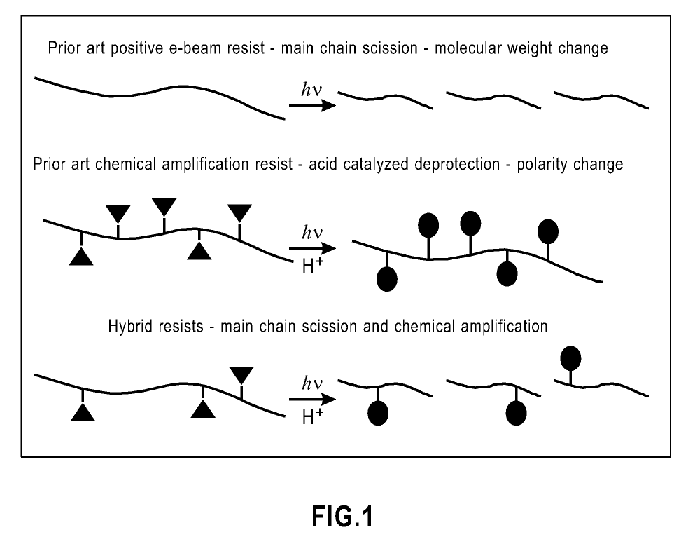

Disclosed are photoresist compositions for deep ultraviolet (DUV, wavelengths of 300 nanometers down to 100 nanometers), extreme ultraviolet (EUV, 13.4 nm), x-ray, and electron beam exposures that combine acid-catalyzed deprotection with main chain scission. The photoresist compositions (also referred to as resist compositions, or simply compositions) comprise at least one polymer capable of main chain scission and chemical amplification, and a photoacid generator (PAG), which when cast on a substrate form a resist layer. High energy exposure of the resist layer causes fragmentation of the sterically hindered polymer chains and the release of acid from the PAG. In a post-exposure bake step, the released acid deprotects acid labile groups of the fragmented polymer chains to further enhance the solubility of the fragmented chains in a developer, as shown schematically in FIG. 1. Unlike prior polymers for resist compositions, the disclosed polymers combine the advantages of high sensitivity and high contrast of chemical amplification with high resolution and low line edge roughness (LER) associated with main chain scission. These combined properties improve upon the low sensitivity for main chain scission and/or poor chemical amplification associated with prior materials for resist compositions.

In this disclosure, reference is made to a number of terms, defined as follows.

As used herein, the phrase “having the formula” or “having the structure” is not intended to be limiting and is used in the same way that the term “comprising” is commonly used.

The term “alkyl” as used herein refers to a linear or branched, saturated hydrocarbon substituent that generally, although not necessarily, contains 1 to about 24 carbon atoms, such as methyl, ethyl, n-propyl, isopropyl, n-butyl, isobutyl, t-butyl, octyl, decyl, tetradecyl, hexadecyl, eicosyl, tetracosyl, and the like. Generally, although again not necessarily, alkyl groups herein contain 1 to about 12 carbon atoms. The term “lower alkyl” intends an alkyl group of 1 to 6 carbon atoms, and the term “cycloalkyl” intends a cyclic alkyl group, typically having 3 to 8, preferably 3 to 7, carbon atoms. The term “substituted alkyl” refers to alkyl substituted with one or more substituent groups, i.e., wherein a hydrogen atom is replaced with a non-hydrogen substituent group, and the terms “heteroatom-containing alkyl” and “heteroalkyl” refer to alkyl substituents in which at least one carbon atom is replaced with a heteroatom such as O, N, or S. If not otherwise indicated, the terms “alkyl” and “lower alkyl” include linear, branched, cyclic, unsubstituted, substituted, and/or heteroatom-containing alkyl and lower alkyl, respectively.

The term “alkylene” as used herein refers to a difunctional linear or branched saturated hydrocarbon linkage, typically although not necessarily containing 1 to about 24 carbon atoms, such as methylene, ethylene, n-propylene, n-butylene, n-hexylene, decylene, tetradecylene, hexadecylene, and the like. Preferred alkylene linkages contain 1 to about 12 carbon atoms, and the term “lower alkylene” refers to an alkylene linkage of 1 to 6 carbon atoms, preferably 1 to 4 carbon atoms. The term “substituted alkylene” refers to an alkylene linkage substituted with one or more substituent groups, i.e., wherein a hydrogen atom is replaced with a non-hydrogen substituent group, and the terms “heteroatom-containing alkylene” and “heteroalkylene” refer to alkylene linkages in which at least one carbon atom is replaced with a heteroatom. If not otherwise indicated, the terms “alkylene” and “lower alkylene” include linear, branched, cyclic, unsubstituted, substituted, and/or heteroatom-containing alkylene and lower alkylene, respectively.

The term “alkoxy” as used herein refers to a group—O-alkyl wherein “alkyl” is as defined above.

The term “aryl” as used herein, and unless otherwise specified, refers to an aromatic substituent containing a single aromatic ring or multiple aromatic rings that are fused together, directly linked, or indirectly linked (such that the different aromatic rings are bound to a common group such as a methylene or ethylene moiety). Preferred aryl groups contain 5 to 24 carbon atoms and either one aromatic ring or 2 to 4 fused or linked aromatic rings, e.g., phenyl, naphthyl, biphenyl, and the like, with more preferred aryl groups containing 1 to 3 aromatic rings, and particularly preferred aryl groups containing 1 or 2 aromatic rings and 5 to 14 carbon atoms. “Substituted aryl” refers to an aryl moiety substituted with one or more substituent groups, and the terms “heteroatom-containing aryl” and “heteroaryl” refer to an aryl group in which at least one ring carbon atom is replaced with a heteroatom. Unless otherwise indicated, the term “aryl” includes substituted and/or heteroaryl species.

The term “arylene” as used herein refers to an aromatic linkage defined as for “aryl” substituents above, but wherein the aryl moiety is bifunctional instead of monofunctional. Unless otherwise indicated, the term “arylene” includes substituted and/or heteroarylene species.

The term “alicyclic” is used to refer to cyclic, non-aromatic compounds, substituents and linkages, e.g., cycloalkanes and cycloalkenes, cycloalkyl and cycloalkenyl substituents, and cycloalkylene and cycloalkenylene linkages. Often, the term refers to bridged bicyclic compounds, substituents, and linkages. Preferred alicyclic moieties herein contain 3 to about 15 carbon atoms. Unless otherwise indicated, the term “alicyclic” includes substituted and/or heteroatom-containing such moieties.

The term “fluorinated” refers to replacement of a hydrogen atom in a molecule or molecular segment with a fluorine atom, and includes perfluorinated moieties. The term “perfluorinated” is also used in its conventional sense to refer to a molecule or molecular segment wherein all hydrogen atoms are replaced with fluorine atoms. Thus, a “fluorinated” methyl group encompasses —CH₂F and —CHF₂ as well as the “perfluorinated” methyl group, i.e., —CF₃ (trifluoromethyl). The term “fluoroalkyl” refers to a fluorinated alkyl group, the term “fluoroalkylene” refers to a fluorinated alkylene linkage, the term “fluoroaryl” refers to a fluorinated aryl substituent, the term “fluoroarylene” refers to a fluorinated arylene linkage, the term “fluoroalicyclic” refers to a fluorinated alicyclic moiety, and the like.

By “substituted” as in “substituted alkyl,” “substituted aryl,” and the like, as alluded to in some of the aforementioned definitions, is meant that in the alkyl, aryl, or other moiety, at least one hydrogen atom bound to a carbon (or other) atom is replaced with a non-hydrogen substituent. Examples of such substituents include, without limitation, functional groups such as halide, hydroxyl, alkoxy, acyl (including alkylcarbonyl(-CO-alkyl) and arylcarbonyl(-CO-aryl)), acyloxy(-O-acyl), alkoxycarbonyl(-(CO)—O-alkyl), aryloxycarbonyl(-(CO)—O-aryl), and silyl (e.g., trialkylsilyl), and hydrocarbyl moieties such as alkyl, aryl, aralkyl(aryl-substituted alkyl), and alkaryl(alkyl-substituted aryl). The aforementioned functional groups may, if a particular group permits, be further substituted with one or more additional functional groups or with one or more hydrocarbyl moieties such as those specifically enumerated above, and analogously, the above-mentioned hydrocarbyl moieties may be further substituted with one or more functional groups or additional hydrocarbyl moieties such as those specifically enumerated.

The term “polymer” is used to refer to a chemical compound that comprises linked monomers, and that may be linear, branched, or crosslinked. The term also encompasses not only homopolymers, but also copolymers, terpolymers, and the like. The term “copolymer,” unless specifically indicated otherwise, refers to a polymer containing at least two different monomer units.

When two substituents are indicated as being “taken together to form a ring,” several possibilities are encompassed. That is, when R and R′ of the following hypothetical compound are indicated as being taken together to form a ring the resulting compounds include (1) those wherein a single spacer atom links the carbon atoms (i.e., R and R′ “taken together” together form a single atom that may or may not be substituted, e.g., CH₂ or O), (2) those wherein a direct covalent bond is formed between R and R′, and (3) those wherein R and R′ are linked through a bifunctional moiety containing one or more spacer atoms, as respectively illustrated in the following structures.

In addition, compounds in which R and R′ are “taken together to form a ring” include compounds in which the linked atoms are not necessarily contained within a terminal group. For example, when R of the above formula is —CH₂CH₃ and R′ is —CH₂CF₃, such that the compound has the structure then compounds in which R and R′ are taken together to form a ring include both.

The term “ring” is intended to include all types of cyclic groups, although the rings of primary interest herein are alicyclic, including cycloalkyl and substituted and/or heteroatom-containing cycloalkyl, whether monocyclic, bicyclic (including bridged bicyclic), or polycyclic. Rings can be substituted and/or heteroatom-containing monocyclic rings.

“Optional” or “optionally” means that the subsequently described circumstance may or may not occur, so that the description includes instances where the circumstance occurs and instances where it does not. For example, the phrase “optionally substituted” means that a non-hydrogen substituent may or may not be present on a given atom, and, thus, the description includes structures wherein a non-hydrogen substituent is present and structures wherein a non-hydrogen substituent is not present.

The term “acid-labile” refers to a molecular segment containing at least one covalent bond that is cleaved upon exposure to acid.

Analogously, the term “acid-inert” refers to a substituent that is not cleaved or otherwise chemically modified upon contact with photogenerated acid.

The terms “photogenerated acid” and “photoacid” are used interchangeably herein to refer to the acid that is created upon exposure of the present photoresist compositions to radiation, i.e., as a result of the radiation-sensitive acid generator in the photoresist compositions.

The term “substantially transparent” as used to describe a polymer that is “substantially transparent” to radiation of a particular wavelength refers to a polymer that has an absorbance of less than about 5.0/micron, preferably less than about 4.0/micron, most preferably less than about 3.5/micron, at a selected wavelength.

In the following description, all amounts, parts, ratios and percentages used herein are by weight unless otherwise specified.

The polymers disclosed herein undergo radiation induced main chain scission and acid-catalyzed deprotection. The polymers comprise repeating units derived from free radical polymerization of two or more monomers, each having an alpha-substituent on a polymerizable vinyl group. “Alpha-substituent” herein means a substituent that is not hydrogen and which is attached to the alpha carbon of the polymerizable vinyl group in an acrylate or a styrene monomer. More particularly the monomers are selected from the group consisting of alpha-substituted acrylates, alpha-substituted styrenes, and combinations thereof. In one embodiment, at least one of the monomers does not form a homopolymer by free radical polymerization. Thus, the polymers comprise repeating units derived from alpha-substituted acrylate monomers of formula (1)

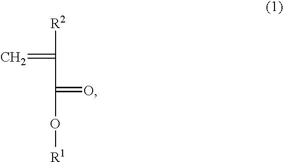

alpha-substituted styrene monomers of formula (2)

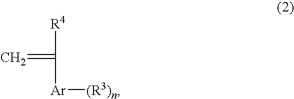

and combinations thereof. In formulas (1) and (2), R² and R⁴ are the alpha-substituents.

The various substituents in formulas (1) and (2) are as follows. R¹ can be hydrogen, an acid-cleavable C₁-C₂₀ moiety optionally substituted with one or more fluorine atoms, or an acid-inert C₁-C₂₀ moiety optionally substituted with one or more fluorine atoms. Acid-inert R¹ moieties include, by way of example, fluorinated alkyl groups, particularly fluorinated lower alkyl groups. Acid-inert moieties also include alkyl and cycloalkyl groups that do not contain a tertiary attachment point, including methyl, ethyl, propyl, iso-propyl, n-butyl, 2-ethylhexyl, phenyl, and substituted phenyl. Acid-cleavable R¹ moieties include tertiary alkyl, e.g., t-butyl, or a cyclic or alicyclic substituent (generally C₆-C₂₀) with a tertiary attachment point such as adamantyl, norbornyl, isobornyl, 2-methyl-2-adamantyl, 2-methyl-2-isobornyl, 2-methyl-2-tetracyclododecenyl, 2-methyl-2-dihydrodicyclopentadienyl-cyclohexyl, 1-methylcyclopentyl, 1-ethylcyclopentyl, 1-methylcyclohexyl, alkylcyclooctyl, dimethylbenzyl, or tetrahydropyranyl. R¹ can also be

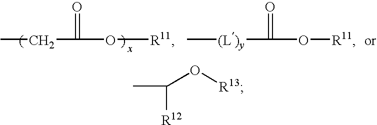

wherein x is in the range of 1 to 8 inclusive, L′ is a hydrocarbylene group optionally substituted with one or more fluorine atoms, y is zero (i.e., L′ is not present) or 1, R¹¹ is optionally substituted hydrocarbyl, typically alkyl or fluorinated alkyl, preferably lower alkyl or fluorinated lower alkyl, and R¹² and R¹³ are lower alkyl or are linked to form a five- or six-membered heterocyclic ring that may or may not contain an additional heteroatom and/or a carbonyl moiety.

Other examples of acid-cleavable groups are set forth in U.S. Pat. No. 4,491,628 to Ito et al., entitled “Positive- and Negative-Working Resist Compositions with Acid-Generating Photoinitiator and Polymer with Acid Labile Groups Pendant from Polymer Backbone,” and in the Handbook of Microlithography, Micromachining, and Microfabrication, Vol. 1: Microlithography, Ed. P. Raj-Coudhury, p. 321 (1997). Still other suitable acid-cleavable groups may be found in U.S. Pat. No. 5,679,495 to Yamachika et al. or in the pertinent literature and texts (e.g., Greene et al., Protective Groups in Organic Synthesis, 2nd Ed. (New York: John Wiley & Sons, 1991)).

R² is generally selected from the group consisting of flourine, lower alkyl, and fluorinated lower alkyl. More particularly, R² is selected from the group consisting of fluorine, chlorine, iodine, methyl, fluoromethyl, difluoromethyl, and trifluoromethyl.

R¹ and R² can also together form a ring, examples of which include the monomers alpha-methylene-gamma-butyrolactone and alpha-methylene succinic anhydride.

Ar is an aromatic moiety, and may be monocyclic, bicyclic or polycyclic. If polycyclic, Ar is typically comprised of not more than about 5 aromatic rings. Bicyclic and polycyclic structures may be fused or linked. For example, bicyclic structures may be biphenyl, a linked substituent, or naphthyl, a fused substituent. Generally, however, Ar will be phenyl, such that the monomer is a styrene analog.

The aromatic moiety Ar can be substituted or unsubstituted. Thus, “n” R³ substituents are bound to Ar, where n is an integer in the range of zero to 5 inclusive, and R³ is a non-hydrogen substituent. When n is zero, the aromatic Ar is unsubstituted, i.e., only hydrogen atoms are bound to the available carbon atoms of the cyclic structure. Non-hydrogen R³ substituents include, by way of example, alkyl, fluorinated alkyl, hydroxyl, alkoxy, fluorinated alkoxy, halogen, and cyano. Optimal halogen substituents are fluorine atoms, and if R³ is alkyl, fluorinated alkyl, alkoxy or fluorinated alkoxy, the substituents will generally be lower alkyl, fluorinated lower alkyl, lower alkoxy or fluorinated lower alkoxy, i.e., containing 1 to about 8 carbon atoms, preferably 1 to about 6 carbon atoms. If Ar is substituted, as noted above, it can contain up to 4 non-hydrogen substituents. However, substituted Ar moieties will generally be substituted with only 1 or 2 substituents, and more particularly 1 substituent.

R³ can further be an acid labile group, for example —OCOOC(CH₃)₃, —OCH₂COOC(CH₃)₃, —O-tetrahydropyranyl, or other acid labile groups commonly employed to protect phenol.

R⁴ is generally selected from the group consisting of fluorine, chlorine, lower alkyl, fluorinated lower alkyl, and the like. More particularly, R⁴ is selected from the group consisting of fluorine, chlorine, methyl, fluoromethyl, difluoromethyl, and trifluoromethyl.

R³ and R⁴, taken together, can also form a five-member or six-member alicyclic or heterocyclic ring that is fused to the Ar group, as shown in the structures MEIN and METL in Table 2 that follows.

Some R¹, R², R³, and R⁴ substituents can adversely affect the absorbance, solubility, or other properties of the resists. These substituents are excluded in formulas (1) and (2). Specifically excluded R² substituents, for example, include hydrogen, substituents having more than three carbons, and substituents having other than carbon or halogen bonded directly to the alpha carbon of the vinyl group. Specifically excluded R¹ substituents include crosslinkable groups such as vinyl, chlorophenyl, and chloromethylphenyl. Specifically excluded R³ substituents include crosslinkable groups such as vinyl, chloro, and chloromethyl. Specifically excluded R⁴ substituents include hydrogen and substituents having more than three carbons bonded directly to the alpha carbon of the vinyl group. Specifically excluded rings formed by R³ and R⁴ include alicyclic or heterocyclic rings larger than six membered rings.

Exemplary monomers of formula (1) include, but are not limited to, the monomers of Table 1.

TABLE 1

| | | |
|---|---|---|
| 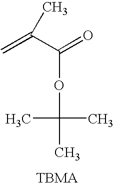 | 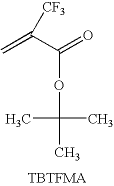 | 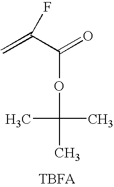 |
| 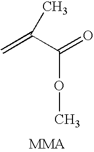 | 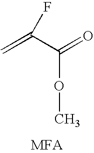 | |

Exemplary monomers of formula (2) include, but are not limited to, those in Table 2.

TABLE 2

| | |
|---|---|
| 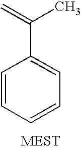 | 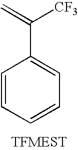 |
| 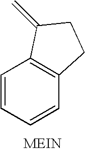 | 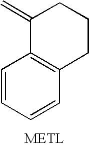 |

The polymers can further comprise repeating units derived from one or more optional comonomers not of formula (1) and formula (2), with the proviso that the desirable characteristics of the copolymer are not adversely affected; for example, chain scission, chemical amplification, film forming properties, solubility, absorbance, and molecular weight. Optional comonomers include fluorine-containing acid-inert monomers such as CF₂═CF₂, (CF₃)₂C═CF₂, (CF₃)₂C═C(CF₃)₂, (CF₃)CH═CH(CF₃), and alpha-trifluoromethylacrylonitrile (TFMAN). Acid-inert monomers that do not contain fluorine include, for example, methacrylnitrile.

Certain comonomers can adversely affect absorbance, molecular weight, chain scission, developability, or other properties of the polymers. Specifically excluded comonomers include acrylates having a alpha-hydrogen substituent on the polymerizable vinyl group; for example, acrylic acid, acrylic acid esters, and acrylic acid amides; vinyl aromatics having a alpha-hydrogen substituent on the polymerizable vinyl group, including unsubstituted styrene and styrene substituted on the aromatic ring with one or two lower alkyl, halogen or hydroxyl groups; butadiene, vinyl acetate, vinyl bromide, and vinylidene chloride.

The polymers are prepared by radical copolymerization, using a suitable free radical initiator. The initiator may be any conventional free radical-generating polymerization initiator. Exemplary initiators include peroxides such as O-t-amyl-O-(2-ethylhexyl)monoperoxycarbonate, dipropylperoxydicarbonate, and benzoyl peroxide (BPO) as well as azo compounds such as azobisisobutyronitrile (AIBN), 2,2′-azobis(2-amidino-propane)dihydrochloride, and 2,2′-azobis(isobutyramide)dihydrate. The initiator is generally present in the polymerization mixture in an amount of from about 0.2 to 5% by weight of the monomers. The resulting polymer typically has a number average molecular weight in the range of approximately 500 to 50,000, more particularly in the range of approximately 1,000 to 20,000.

While t-butyl 2-trifluoromethylacrylate (TBTFMA) and alpha-methylstyrene (MEST) are reluctant to undergo radical homopolymerization due to steric hindrance, t-butyl methacrylate (TBMA), methyl methacrylate (MMA), 2-fluoroacrylates (FAs), alpha-methyleneindane (MEIN), and alpha-methylenetetralone (METL) homopolymerize with a varying degree of ease. Copolymers made from monomers that do not undergo homopolymerization under free radical polymerization conditions are more desirable in terms of main chain scission susceptibility, but incorporation of one homopolymerizable monomer is advantageous in terms of yield and molecular weights. Each repeat unit in the disclosed polymers for the resist compositions has an alpha-substituent on the polymerizable vinyl group. The copolymers are sterically hindered, rendering them susceptible to main chain scission upon irradiation.

Thus, although the polymer can be a homopolymer, in general copolymers provide for more desirable balance in molecular weight and main chain scission susceptibility. More particularly, the polymer is a copolymer comprising residues derived from two or more monomers selected from the group consisting of TBMA, TBTFMA, TBFA, MMA, MFA, MEST, TFMEST, MEIN, METL. Even more particularly, the polymer is a copolymer consisting essentially of, or consisting exclusively of, repeating units derived from two or more monomers selected from the group consisting of TBMA, TBTFMA, TBFA, MMA, MFA, MEST, TFMEST, MEIN, and METL. In one embodiment, when MMA is present in the copolymer, also present is a monomer selected from the group consisting of TBMA, TBTFMA, TBFA, MEST, TFMEST, MEIN, METL and combinations thereof.

Representative copolymers and terpolymers formed from the above-mentioned monomers are listed in Table 3. These include but are not limited to TBFA-MEIN copolymer, TBFA-MEST copolymer; TBFA-MFA-MEIN terpolymer; TBFA-MFA-MEST terpolymer; TBFA-MMA copolymer; TBFA-METL copolymer; TBMA-MEST copolymer; TBMA-MFA copolymer; TBMA-MMA copolymer; TBMA-TFMEST copolymer; TBMA-METL copolymer; TBTFMA-MEST copolymer; TBTFMA-MMA copolymer; TBTFMA-MEST copolymer; TBTFMA-METL copolymer; and TBTFMA-MFA copolymer. The polymer name contains the component monomers separated by a hyphen. The repeat unit derived from each of the monomers can be present in the polymer in an amount of more than 0 mole percent to less than 100 mole percent based on a total of 100 mole percent for all monomer repeat units in the polymer.

TABLE 3

| | |
|---|---|
| 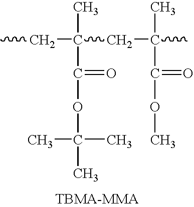 | 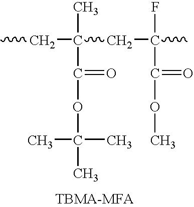 |
| 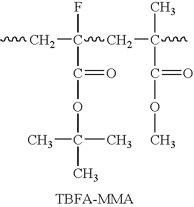 | 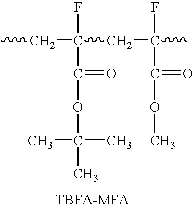 |
| 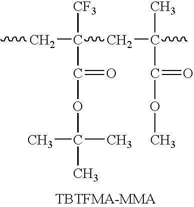 | 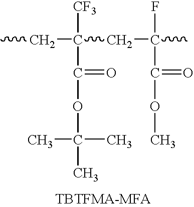 |
| 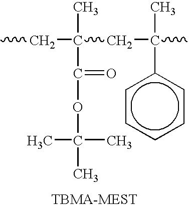 | 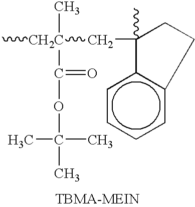 |
| 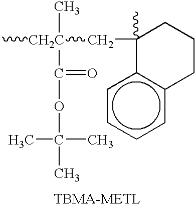 | 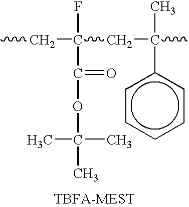 |
| 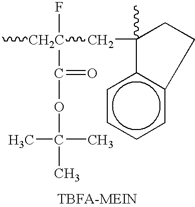 | 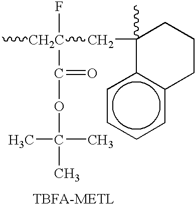 |
| 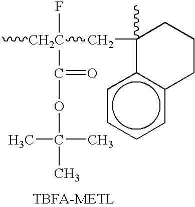 | 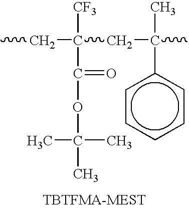 |
| 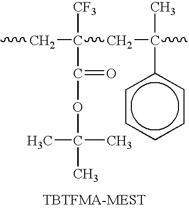 | 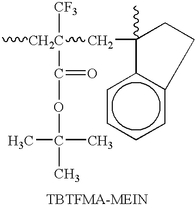 |
| 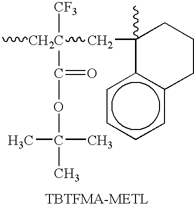 | 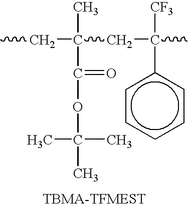 |

To illustrate the advantage of the polymers, poly(methyl methacrylate) (PMMA) is the most commonly employed high resolution positive e-beam resist, but its sensitivity is very low (Gs=1.3, where Gs is a measure of the main chain bond scission yield per 100 eV dose). By replacing a fraction of the methyl ester in PMMA with t-butyl ester by copolymerization of TBMA and MMA, the sensitivity increases due to the propensity of the copolymer to undergo acid-catalyzed deprotection, a change in polarity, in addition to the main chain cleavage. Furthermore, replacing the alpha-methyl of the TBMA-MMA copolymer with CF₃ by copolymerization of TBTFMA with MMA increases the main chain scission susceptibility. A homopolymer of methyl 2-trifluoromethylacrylate (MTFMA) and its copolymer with MMA have higher Gs values (Gs=2.5-3.4), thus higher sensitivity than PMMA.

MEST does not undergo radical homopolymerization but its anionic or cationic homopolymer degrades by irradiation in sharp contrast to polystyrene, which crosslinks when irradiated. Replacement of the methacrylate alpha-CH₃ group with CF₃ increases the backbone scission susceptibility. Thus, alpha-trifluoromethylstyrene (TFMEST) does not homopolymerize by radical initiation but it is more reactive than styrene in radical copolymerization. Its copolymer with TBMA undergoes main chain scission and acid-catalyzed deprotection. The cyclized indane MEIN can homopolymerize due to reduced steric hindrance through cyclization. MEIN provides higher yield and molecular weight than MEST. The six-membered analog, METL, does not polymerize well, presumably due to lack of conjugation between the C═C double bond and the benzene ring.

In a more specific embodiment, the photoresist composition comprises a polymer consisting essentially of two different alpha-substituted acrylate units, one of which bears an acid-labile protecting group. The alpha-substituted acrylate units can be selected from the group consisting of TBMA, TBTFMA, TBFA, MMA, MFA and combinations thereof. In another more specific embodiment, the photoresist composition comprises a polymer consisting essentially of an alpha-substituted acrylate unit and an alpha-substituted styrene unit, wherein the alpha-substituted acrylate unit bears an acid-labile protecting group. The alpha-substituted acrylate units can be selected from the group consisting of TBMA, TBTFMA, TBFA, MMA, MFA and combinations thereof, and the alpha-substituted styrene can be selected from the group consisting of MEST, TFMEST, MEIN, METL and combinations thereof. In yet another specific embodiment, the photoresist composition comprises a polymer consisting essentially of an alpha-substituted acrylate unit and an alpha-substituted styrene unit, wherein the alpha-substituted styrene unit bears an acid-labile aryl substituent selected from the group consisting of —OCOOC(CH₃)₃, —OCH₂COOC(CH₃)₃, and —O-tetrahydropyranyl.

In even more specific embodiments, the resist copolymer can comprise monomer repeat units as follows.

The resist copolymer can be a TBFA-MEIN copolymer, wherein a monomer repeat unit derived from TBFA is present in an amount of 10 to 60 mole percent based on a total of 100 mole percent for all monomer repeat units in the polymer.

The resist polymer can be a TBFA-MEST copolymer, wherein a repeat unit derived from TBFA is present in an amount of 20 to 80 mole percent based on a total of 100 mole percent for all monomer repeat units in the polymer.

The resist copolymer can be a TBFA-MFA-MEIN copolymer, wherein a monomer repeat unit derived from TBFA is present in an amount of 20 to 60 mole percent and a monomer repeat unit derived from MFA is present in an amount of 0 to 30 mole percent based on a total of 100 mole percent for all monomer repeat units in the polymer.

The resist copolymer can be a TBFA-MFA-MEST copolymer, wherein a monomer repeat unit derived from TBFA is present in an amount of 50 to 70 mole percent and a monomer repeat unit derived from MFA is present in an amount of 0 to 50 mole percent based on a total of 100 mole percent for all monomer repeat units in the polymer.

The resist copolymer can be a TBFA-MMA copolymer, wherein a monomer repeat unit derived from TBFA is present in an amount of 10 to 90 mole percent based on a total of 100 mole percent for all monomer repeat units in the polymer.

The resist copolymer can be a TBMA-MEST copolymer, wherein a monomer repeat unit derived from TBMA is present in an amount of 50 to 80 mole percent, based on a total of 100 mole percent for all monomer repeat units in the polymer.

The resist copolymer can be a TBMA-MFA copolymer, wherein a monomer repeat unit derived from TBMA is present in an amount of 15 to 80 mole percent, based on a total of 100 mole percent for all monomer repeat units in the polymer.

The resist copolymer can be a TBMA-MMA copolymer, wherein a monomer repeat unit derived from TBMA is present in an amount of 10 to 90 mole percent, based on a total of 100 mole percent for all monomer repeat units in the polymer.

The resist copolymer can be a TBMA-TFMEST copolymer, wherein a monomer repeat unit derived from TBMA is present in an amount of 30 to 90 mole percent, based on a total of 100 mole percent for all monomer repeat units in the polymer.

The resist copolymer can be a TBTFMA-MEST copolymer, wherein a monomer repeat unit derived from TBTFMA is present in an amount of 30 to 50 mole percent, based on a total of 100 mole percent for all monomer repeat units in the polymer.

The resist copolymer can be a TBTFMA-MMA copolymer, wherein a monomer repeat unit derived from TBTFMA is present in an amount of 10 to 50 mole percent, based on a total of 100 mole percent for all monomer repeat units in the polymer.

The resist copolymer can be a TBTFMA-MEST copolymer, wherein a monomer repeat unit derived from TBTFMA is present in an amount of 35 to 50 mole percent, based on a total of 100 mole percent for all monomer repeat units in the polymer.

The resist copolymer can be a TBTFMA-MFA copolymer, wherein a monomer repeat unit derived from TBTFMA is present in an amount of 20 to 50 mole percent, based on a total of 100 mole percent for all monomer repeat units in the polymer.

The photoresist composition also comprises a photoacid generator, with the polymer representing up to about 99 wt. % of the solids included in the composition, and the photoacid generator representing approximately 0.5 to 10 wt. % of the solids contained in the composition. Other components and additives (e.g., dissolution modifying additives such as dissolution inhibitors) may also be present.

The photoacid generator can be any compound that, upon exposure to radiation, generates a strong acid and is compatible with the other components of the photoresist composition. Examples of photochemical acid generators (PAGs) include, but are not limited to, α-(trifluoromethylsulfonyloxy)-bicyclo[2.2.1]hept-5-ene-2,3-dicarboximide (MDT), onium salts, aromatic diazonium salts, sulfonium salts, diaryliodonium salts and sulfonic acid esters of N-hydroxyamides or N-hydroxyimides, as disclosed in U.S. Pat. No. 4,731,605. Also, a PAG that produces a weaker acid such as the dodecane sulfonate of N-hydroxy-naphthalimide (DDSN) may be used. Combinations of PAGs can be used. Generally, desirable acid generators have high thermal stability (are stable to temperatures greater than 140° C.) so they are not degraded during pre-exposure processing. In addition to MDT and DDSN, sulfonate PAGs include sulfonate salts, sulfonated esters and sulfonyloxy ketones. U.S. Pat. No. 5,344,742 to Sinta et al., and J. Photopolymer Science and Technology, 4:337 (1991), disclose sulfonate PAGs, including benzoin tosylate, t-butylpheny-α-(p-toluenesulfonyloxy)acetate and t-butyl-α-(p-toluenesulfonyloxy)-acetate. Still other PAGs include onium salts, in particular onium salts that contain weakly nucleophilic anions. Examples of such anions are the halogen complex anions of divalent to heptavalent metals or non-metals, for example, Sb, B, P, and As. Additional examples of onium salts are aryl-diazonium salts, halonium salts, aromatic sulfonium salts and sulfoxonium salts or selenium salts, (e.g., triarylsulfonium and diaryliodonium hexafluoroantimonates, hexafluoroarsenates, trifluoromethanesulfonates and others). A particular diaryliodonium salt is iodonium perfluorooctanesulfonate and is disclosed in U.S. Pat. No. 6,165,673 to Breyta et al. Examples of other onium salts can be found in U.S. Pat. Nos. 4,442,197, 4,603,101, and 4,624,912. Still other acid generators include the family of nitrobenzyl esters, and the s-triazine derivatives. s-Triazine acid generators are disclosed, for example, in U.S. Pat. No. 4,189,323.

Still other acid generators include: sulfonyloxynaphthalimides such as N-camphorsulfonyloxynaphthalimide and N-pentafluorophenylsulfonyloxynaphthalimide; ionic iodonium sulfonates, e.g., diaryl iodonium (alkyl or aryl) sulfonate and bis-(di-t-butylphenyl)-iodonium camphanylsulfonate; perfluoroalkanesulfonates, such as perfluoropentanesulfonate, perfluorooctanesulfonate, and perfluoromethanesulfonate; aryl (e.g., phenyl or benzyl)triflates and derivatives and analogs thereof, e.g., triphenylsulfonium triflate (TPSOTf) or bis-(t-butylphenyl)iodonium triflate; triphenylsulfonium nonaflate (TPSONf); pyrogallol derivatives (e.g., trimesylate of pyrogallol); trifluoromethanesulfonate esters of hydroxyimides; α,α′-bis-sulfonyl-diazomethanes; sulfonate esters of nitro-substituted benzyl alcohols; naphthoquinone-4-diazides; and alkyl disulfones. Other photoacid generators are disclosed in Reichmanis et al. (1991), Chemistry of Materials 3:395, and in U.S. Pat. No. 5,679,495 to Yamachika et al. Additional acid generators useful in conjunction with the photoresist compositions and methods provided herein will be known to those skilled in the art and/or are described in the pertinent literature.

With a positive photoresist composition, a dissolution modifying additive, generally although not necessarily a dissolution inhibitor, can be optionally included. If dissolution inhibitors are present, they will typically be present in an amount of about 1 wt. % to 40 wt. %, more particularly about 5 wt. % to 30 wt. %, of the total solids.

Dissolution inhibitors have high solubility in the resist composition and the solvent used to prepare solutions of the resist composition (e.g., propylene glycol methyl ether acetate, or “PGMEA”), exhibit strong dissolution inhibition, have a high exposed dissolution rate, are substantially transparent at the wavelength of interest, may exhibit a moderating influence on glass transition temperature (Tg), have strong etch resistance, and display good thermal stability (i.e., stability at temperatures of about 140° C. or greater). More particularly, dissolution inhibitors include, but are not limited to, bisphenol A derivatives, e.g., wherein one or both hydroxyl moieties are converted to a t-butoxy substituent or a derivative thereof such as a t-butoxycarbonyl or t-butoxycarbonylmethyl group; fluorinated bisphenol A derivatives such as CF₃-bisphenol A-OCH₂(CO)—O-tBu (6F-bisphenol A protected with a t-butoxycarbonylmethyl group); normal or branched chain acetal groups such as 1-ethoxyethyl, 1-propoxyethyl, 1-n-butoxyethyl, 1-isobutoxy-ethyl, 1-t-butyloxyethyl, and 1-t-amyloxyethyl groups; and cyclic acetal groups such as tetrahydrofuranyl, tetrahydropyranyl, and 2-methoxytetrahydro-pyranyl groups; androstane-17-alkylcarboxylates and analogs thereof, wherein the 17-alkylcarboxylate at the 17-position is typically lower alkyl. Examples of such compounds include lower alkyl esters of cholic, ursocholic and lithocholic acid, including methyl cholate, methyl lithocholate, methyl ursocholate, t-butyl cholate, t-butyl lithocholate, t-butyl ursocholate, and the like (see, e.g., Allen et al. (1995) J. Photopolym. Sci. Technol., cited supra); hydroxyl-substituted analogs of such compounds (ibid.); and androstane-17-alkylcarboxylates substituted with 1 to 3 C₁-C₄ fluoroalkyl carbonyloxy substituents, such as t-butyl trifluoroacetyllithocholate (see, e.g., U.S. Pat. No. 5,580,694 to Allen et al.).

The resist composition can further comprise acid-diffusion controlling agents, or base quenchers. A wide variety of compounds with varying basicity may be used as stabilizers and acid-diffusion controlling additives. They may include nitrogenous compounds such as aliphatic primary, secondary, and tertiary amines, cyclic amines such as piperidines, pyrimidines, morpholines, aromatic heterocycles such as pyridines, pyrimidines, purines, imines such as diazabicycloundecene, guanidines, imides, amides, and others. Ammonium salts may also be used, including ammonium, primary, secondary, tertiary, and quaternary alkyl- and arylammonium salts of alkoxides including hydroxide, phenolates, carboxylates, aryl and alkyl sulfonates, sulfonamides, and others. Other cationic nitrogenous compounds including pyridinium salts and salts of other heterocyclic nitrogenous compounds with anions such as alkoxides including hydroxide, phenolates, carboxylates, aryl and alkyl sulfonates, sulfonamides, and the like may also be employed.

The resist composition typically also comprises a solvent. Greater than 50 percent of the total mass of the resist formulation is typically composed of the solvent, more particularly greater than 80 percent. The choice of solvent is governed by many factors not limited to the solubility and miscibility of resist components, the coating process, and safety and environmental regulations. Additionally, inertness to other resist components is desirable. It is also desirable that the solvent possess the appropriate volatility to allow uniform coating of films yet also allow significant reduction or complete removal of residual solvent during the post-application bake process. See, e.g., Introduction to Microlithography, Eds. Thompson et al. In addition to the above components, the photoresist compositions provided herein generally include a casting solvent to dissolve the other components so that the overall composition may be applied evenly on the substrate surface to provide a defect-free coating. Where the photoresist composition is used in a multilayer imaging process, the solvent used in the imaging layer photoresist is preferably not a solvent to the underlayer materials, otherwise the unwanted intermixing may occur. No restriction is placed on the selection of the solvent. Casting solvents can generally be chosen from ether-, ester-, hydroxyl-, and ketone-containing compounds, or mixtures of these compounds. Examples of appropriate solvents include carbon dioxide, cyclopentanone, cyclohexanone, ethyl 3-ethoxypropionate (EEP), a combination of EEP and gamma-butyrolactone (GBL), lactate esters such as ethyl lactate, alkylene glycol alkyl ether esters such as PGMEA, alkylene glycol monoalkyl esters such as methyl cellosolve, butyl acetate, and 2-ethoxyethanol. Preferred solvents include ethyl lactate, propylene glycol methyl ether acetate, ethyl 3-ethoxypropionate and their mixtures. The above list of solvents is for illustrative purposes only and should not be viewed as being comprehensive nor should the choice of solvent be viewed as limiting in any way. Those skilled in the art will recognize that any number of solvents or solvent mixtures may be used.

The resist composition can additionally, if necessary or desirable, include customary additives such as dyes, sensitizers, other additives used as stabilizers, coating aids such as surfactants or anti-foaming agents, adhesion promoters and plasticizers. Dyes may be used to adjust the optical density of the formulated resist and sensitizers which enhance the activity of photoacid generators by absorbing radiation and transferring it to the photoacid generator. Examples include aromatics such as functionalized benzenes, pyridines, pyrimidines, biphenylenes, indenes, naphthalenes, anthracenes, coumarins, anthraquinones, other aromatic ketones, and derivatives and analogs of any of the foregoing. Surfactants may be used to improve coating uniformity, and include a wide variety of ionic and non-ionic, monomeric, oligomeric, and polymeric species. Likewise, a wide variety of anti-foaming agents may be employed to suppress coating defects. Adhesion promoters may be used as well; again, a wide variety of compounds may be employed to serve this function. A wide variety of monomeric, oligomeric, and polymeric plasticizers such as oligo- and polyethyleneglycol ethers, cycloaliphatic esters, and non-acid reactive steroidally derived materials may be used as plasticizers, if desired. However, neither the classes of compounds nor the specific compounds mentioned above are intended to be comprehensive and/or limiting. One versed in the art will recognize the wide spectrum of commercially available products that may be used to carry out the types of functions that these customary additives perform.

Typically, the sum of all customary additives comprises less than 20 percent of the solids included in the resist formulation, more specifically, less than 5 percent.

Also disclosed is a method of forming a positive relief image comprising (i) disposing on a substrate a layer comprising a polymer capable of radiation induced main chain scission and acid-catalyzed deprotection, wherein the polymer is derived by free radical polymerization of two or more monomers, each having an alpha-substituent on a polymerizable vinyl group; and a photo-acid generator; (ii) imagewise irradiating the layer to form fragmented chains of the polymer in an irradiated area; (iii) heating the layer to effect acid-catalyzed deprotection of the fragmented chains of polymer in the irradiated area; and (iv) developing the layer with a developer to form the positive relief image disposed on the substrate. Heating the film at an elevated temperature increases the relative solubility of the fragmented resist chains in the developer compared to the unexposed areas of the layer, resulting in high sensitivity and image contrast. In one embodiment, the layer further comprises a base quencher. In another embodiment, the polymer consists essentially of two or more monomers selected from the above-described alpha-substituted acrylates, alpha-substitituted styrenes, and combinations thereof; wherein at least one monomer comprises an acid-labile protecting group. In still another embodiment, the polymer is selected from the group consisting of: TBFA-MEIN copolymer, TBFA-MEST copolymer; TBFA-MFA-MEIN terpolymer; TBFA-MFA-MEST terpolymer; TBFA-MMA copolymer; TBFA-METL copolymer; TBMA-MEST copolymer; TBMA-MFA copolymer; TBMA-MMA copolymer; TBMA-TFMEST copolymer; TBMA-METL copolymer; TBTFMA-MEST copolymer; TBTFMA-MMA copolymer; TBTFMA-MEST copolymer; TBTFMA-METL copolymer; and TBTFMA-MFA copolymer

The first step involves coating the substrate with a layer comprising the photoresist composition. The substrate can be a semiconductor, ceramic, or a metal. More particularly, the substrate is quartz, Cr-coated quartz, Cr-coated glass, silicon dioxide, silicon nitride, or silicon oxynitride. The substrate may or may not be coated with an organic anti-reflective layer prior to deposition of the resist composition.

The surface of the substrate can be cleaned by standard procedures before the film is deposited thereon. Solvents for the composition are as described in the preceding section, and include, for example, cyclohexanone, ethyl lactate, and propylene glycol methyl ether acetate. The layer can be coated on the substrate using art-known techniques such as spin or spray coating, or doctor blading. Before the layer has been exposed to radiation, the layer can be heated to an elevated temperature of about 90° C. to 150° C. for a short period of time (post apply bake, PAB), typically on the order of about 1 minute. The dried film layer has a thickness of about 0.02 to 5.0 microns, about 0.05 to 2.5 microns, and most specifically about 0.05 to 1.0 microns. The radiation may be deep ultraviolet, electron beam, EUV, or x-ray.

The radiation is absorbed by the resist to effect fragmentation of the polymer main chain. The radiation is also absorbed by the photochemical acid generator to generate free acid, which with heating in a post exposure bake (PEB), generally to a temperature of about 90° C. to 150° C. for a short period of time, on the order of about 1 minute, alters the solubility of the exposed resist in developer by reacting with acid-labile groups of the fragmented chains. In one embodiment, heating causes the resist to become more soluble in the developer, for example by causing cleavage of acid-labile pendant groups and formation of functional groups, such as carboxylic acids, that render the resist more soluble in the developer. It will be appreciated by those skilled in the art that the aforementioned description applies to a positive resist.

The last step involves development of the image with a developer. Developers can include an organic solvent, aqueous base, or a combination thereof. Preferably, the aqueous base does not comprise metal ions, such as the industry standard developer tetramethylammonium hydroxide or choline. Other developers can be solvents, including organic solvents or carbon dioxide (in the liquid or supercritical state), as disclosed in U.S. Pat. No. 6,665,527 to Allen et al. Because the copolymer of the resist composition is substantially transparent at 248 nm, the resist composition is uniquely suitable for use at that wavelength. However, the resist composition may also be used with deep ultraviolet wavelengths, for example 193 nm (all-acrylate resists), or with EUV (e.g., at 13 nm), electron beam, or x-ray radiation.

The positive relief image in the developed resist layer may then be transferred to the material of the underlying substrate. Typically, the transfer is achieved by reactive ion etching of the substrate, or some other etching technique wherein the relief image serves as a mask providing selective contact between the substrate and a substrate etchant. Thus, the resist compositions provided herein and resulting resist layers can be used to create patterned substrate layer structures such as metal wiring lines, holes for contacts or vias, insulation sections (e.g., damascene trenches or shallow trench isolation), trenches for capacitor structures, etc. as might be used in the design of integrated circuit devices. Accordingly, the processes for making these features involves, after development with a suitable developer as above, etching the layer(s) underlying the developed resist layer at spaces in the relief image whereby a patterned substrate layer or substrate section is formed, and removing any remaining resist from the substrate. In some instances, a hard mask may be used below the resist layer to facilitate transfer of the pattern to a further underlying material layer or section. In the manufacture of integrated circuits, circuit patterns can be formed in the exposed areas after resist development by coating the substrate with a conductive material, e.g., a metallic material, using known techniques such as evaporation, sputtering, plating, chemical vapor deposition, or laser-induced deposition. Dielectric materials may also be deposited by similar means during the process of making circuits. Inorganic ions such as boron, phosphorous, or arsenic can be implanted in the substrate in the process for making p-doped or n-doped circuit transistors. Examples of such processes are disclosed in U.S. Pat. Nos. 4,855,017, 5,362,663, 5,429,710, 5,562,801, 5,618,751, 5,744,376, 5,801,094, and 5,821,469. Other examples of pattern transfer processes are described in Chapters 12 and 13 of Moreau, Semiconductor Lithography, Principles, Practices, and Materials (Plenum Press, 1988). It should be understood that the method is not limited to any specific lithographic technique or device structure.

It is to be understood that while photoresist compositions have been described in conjunction with specific embodiments thereof, that the foregoing description as well as the examples that follow are intended to be illustrative and non-limiting. Other aspects, advantages and modifications of the disclosed photoresist compositions will be apparent to those skilled in the pertinent art.

### EXAMPLES

The following copolymers were prepared by free radical copolymerization with 2,2′-azobis(isobutyronitrile) (AIBN) in bulk or in solvent (e.g., ethyl acetate and methyl ethyl ketone (MEK)) at 60° C. to 70° C., and their compositions determined by inverse gate ¹³C-NMR in the presence of Cr(acac)₃.

### Measurements.

¹H, ¹⁹F, and ¹³C NMR spectra were obtained at room temperature on a Bruker Avance 400 spectrometer. Quantitative ¹³C NMR was run at room temperature in acetone-d₆ or in CDCl₃ in an inverse-gated ¹H-decoupled mode using Cr(acac)₃ as a relaxation agent on a Bruker Avance 400 spectrometer. Thermogravimetric analysis (TGA) was performed at a heating rate of 5° C./min in N₂ on a TA Instrument Hi-Res TGA 2950 Thermogravimetric Analyzer. Differential scanning calorimetry (DSC) was performed at a heating rate of 10° C./min on a TA Instruments DSC 2920 modulated differential scanning calorimeter. Number average, Mₙ, and weight average, M_{w}, molecular weights of the polymers were measured in tetrahydrofuran (THF) on a Waters Model 150 gel permeation chromatograph (GPC) relative to polystyrene standards. Film thickness was measured on a Tencor alpha-step 2000. A quartz crystal microbalance (QCM) was used to study the dissolution kinetics of the polymer films in developer solvents, by measuring frequency and resistance using 5 MHz crystals.

### Materials.

Methyl methacrylate (MMA), t-butyl methacrylate (TBMA), and alpha-methylstyrene (MEST) were purchased from Aldrich. Methyl 2-trifluoromethylacrylate (MTFMA, synthesis of which is described in Macromolecules, 15, 915 (1982), was obtained from SynQuest Laboratories. t-Butyl 2-trifluoromethylacrylate (TBTFMA), synthesis of which is described in Proc. SPIE, 4345, 273 (2001), was obtained from Central Glass. Methyl 2-fluoroacrylate (MFA) (Macromolecules, 13, 1031 (1980)) and t-butyl 2-fluoroacrylate (TBFA) were obtained from SynQuest Laboratories. 2-Trifluoromethylstyrene (TFMEST) was synthesized as described in J. Polym. Sci., Polym. Chem. Ed., 26, 89 (1988). alpha-Methyleneindane (MeIN) was synthesized according to the procedure described in J. Polym. Sci., Part A, Polym. Chem. Ed., 29, 1779 (1991).

alpha-Methylenetetralone (METL) was prepared according to the following procedure. Potassium t-butoxide (13.5 g, 120 mmol) was added to a mixture of methyltriphenylphosphonium iodide (49 g, 120 mmol) in diethyl ether (700 mL) under nitrogen atmosphere. The mixture was stirred for 1 hour. alpha-Tetralone (14.6 g, 120 mmol) was added to the mixture and the mixture was stirred overnight. The resulting mixture was added to hexanes and the mixture was filtered through Celite. The filtrate was concentrated under vacuum to give an oil. Silica-gel column chromatography with hexanes as eluent followed by evaporation of solvents gave the desired alpha-methylenetetralone (12 g, 83% yield).

alpha-Methyleneindane (MEIN) was prepared according to the following procedure. Potassium t-butoxide (13.5 g, 120 mmol) was added to a mixture of methyltriphenylphosphonium iodide (49 g, 120 mmol) in diethyl ether (500 mL) under nitrogen atmosphere. The mixture was stirred for 1 hour. 1-Indanone (13.2 g, 120 mmol) was added to the mixture and the mixture was stirred overnight. The resulting mixture was added to hexanes and the mixture was filtered through Celite. The filtrate was concentrated under vacuum to give an oil. Silica-gel column chromatography with hexanes as eluent followed by evaporation of solvents gave the desired alpha-methyleneindane (10 g, 77% yield).

Propylene glycol methyl ether acetate (PGMEA) was employed as a casting solvent primarily but other solvents such as cyclopentanone and gamma-butyrolactone (GBL) were also used. Triphenylsulfonium triflate (TPSOTf) and Triphenylsulfonium nonaflate (TPSONf) were the photochemical acid generators (PAGs) employed. Resist formulations were prepared by adding PAG and a base quencher (tetrabutylammonium hydroxide (TBAH)) to polymer solutions. The developer was 0.26 N tetramethylammonium hydroxide (TMAH), isopropanol, or a mixture of isopropanol with methyl isobutyl ketone (MIBK).

### Copolymer Synthesis.

### Example 1

### TBMA-TFMEST (1:1 mol/mol in Feed)

A mixture of TBMA (2.8512 g), TFMEST (3.4429 g), and 2,2′-azobisisobutyronitrile (AIBN, 0.2634 g) was deaerated by bubbling N₂ for 30 min and heated at 60° C. in a N₂ atmosphere for 6 days 17 hrs. The resulting solid was dissolved in acetone and slowly poured into a mixture of methanol and water (3/1 vol/vol) and the precipitated polymer was isolated by filtration and washed with a methanol/water (3/1 vol/vol) mixture. The polymer was dried in a vacuum oven at 60° C. overnight, yielding 2.6456 g (42.0%) of white solid. The analyzed composition of the copolymer was TBMA/TFMEST=83/17 (mol/mol) according to inverse-gated ¹³C NMR in acetone-d₆ using Cr(acac)₃ as a relaxation agent. The number and weight average molecular weights relative to polystyrene standards, determined by GPC in THF, were Mₙ=3,500 and M_{w}=5,200. Its glass transition temperature (T_{g}) was 60° C.

### Example 2

### TBTFMA-MEST (1:1 mol/mol in Feed)

A mixture of TBTFMA (19.628 g), MEST (11.850 g), and AIBN (1.3141 g) was deaerated by bubbling N₂ for 30 min and heated at 60° C. in N₂ for 3 days. AIBN (0.6416 g) was added and the heating was continued for another 4 days. The polymer was precipitated in methyl perfluoro-n-propyl ether, filtered, and washed with methyl perfluoro-n-propyl ether. After drying in a vacuum oven at room temperature overnight, the polymer yield amounted to 6.055 g (19%). The copolymer composition was TBTFMA/MEST=39/61 (mol/mol). Mₙ=1,400 and M_{w}=1,900.

### Example 3

### TBMA-MEST (1:1 mol/mol in Feed)

A mixture of TBMA (5.6945 g), MEST (4.7339 g), and AIBN (0.2636 g) was deaerated by bubbling N₂ for 30 min and heated at 60° C. in N₂ for 7 days. The reaction mixture was diluted with acetone and poured slowly into methanol. The precipitated polymer was recovered by filtration and washed with methanol. The copolymer was dried in a vacuum oven at 60° C. overnight. The copolymer yield was 1.725 g (15%). Mₙ=8,100 and M_{w}=11,500. The composition was TBMA/MEST=57/43 (mol/mol) and its T_{g} was 144° C.

### Example 4

### TBMA-MEST (2:3 mol/mol in Feed)

A mixture of TBMA (11.389 g), MEST (14.275 g), and AIBN (1.3138 g) was deaerated by bubbling N₂ for 30 min and heated at 60° C. in N₂ for 2 days. AIBN (0.6551 g) was added and the copolymerization reaction was run for another 3 days. The reaction mixture was diluted with acetone and poured slowly into methanol. The precipitated polymer was recovered by filtration, washed with methanol, and dried in a vacuum oven at 60° C. overnight. The copolymer yield was 12% and the composition was TBMA/MEST=50/50 (mol/mol). Mₙ=1,800 and M_{w}=2,100. T_{g} was 138° C.

### Example 5

### TBFA-MEST (1:1 mol/mol in Feed)

A mixture of TBFA (2.9287 g), MEST (2.3743 g), and AIBN (0.2629 g) was deaerated by bubbling N₂ for 30 min and heated at 60° C. for 5 days. The resulting solid was dissolved in acetone and slowly poured into hexanes. The precipitated copolymer was isolated by filtration, washed with hexanes, and dried in a vacuum oven at 50° C. overnight. The copolymer yield was 32% (1.7160 g) and the composition was TBFA/MEST=47/53 (mol/mol). Mₙ=5,700 and M_{w}=9,300. T_{g} was 97° C.

### Example 6

### TBFA-MEIN (1:1 mol/mol in Feed)

A mixture of TBFA (2.9358 g), MEIN (2.6286 g), and AIBN (0.2629 g) was deaerated by bubbling N₂ for 30 min and heated at 60° C. in N₂ for 7 days. The reaction mixture was dissolved in ethyl acetate and slowly poured into hexanes. The precipitated polymer was recovered by filtration and washed with hexanes. The copolymer was dried in a vacuum oven at 50° C. overnight. The yield was 22% (1.2165 g) and the composition was TBFA/MEIN=39/61 (mol/mol). Mₙ=6,700 and M_{w}=13,000. T_{g} was 127° C.

### Example 7

### TBTFMA-MMA (1:4 mol/mol in Feed)

A mixture of TBTFMA (7.858 g), MMA (16.076 g), and AIBN (0.6573 g) was deaerated by bubbling N₂ for 30 min and heated at 60° C. in N₂ for 50 min. The resulting solid was dissolved in acetone and slowly poured into methanol. The precipitated polymer was isolated by filtration, washed with methanol, and dried in a vacuum oven at 50° C. overnight. The copolymer yield was 62% (14.72 g) and the composition was TBTFMA/MMA=14/86 (mol/mol). Mₙ=33,900 and M_{w}=75,100. T_{g} was 125° C.

### Example 8

### TBMA-MMA (1:9 mol/mol in Feed)

A solution of TBMA (3.171 g), MMA (18.020 g), and AIBN (0.6565 g) in 35.06 g of ethyl acetate was deaerated by bubbling N₂ for 30 min and heated in N₂ at 60° C. for 2 days. The reaction mixture was diluted with acetone and slowly poured into methanol. The precipitated polymer was isolated by filtration, washed with methanol, and dried in a vacuum oven at 60° C. overnight. The copolymer yield was 85% (18.10 g) and the composition was TBMA/MMA=10/90 (mol/mol). Mₙ=39,200 and M_{w}=62,100. T_{g} was 115° C.

### Example 9

### TBMA-MMA (2:3 mol/mol in Feed)

TBMA (2.40 g), MMA (2.60 g), AIBN (0.198 g), and methyl ethyl ketone (MEK, 14.8 g) were placed in a round-bottomed flask and a freeze-thaw cycle was repeated a couple of times. Polymerization reaction was carried out at 60° C. for 65 hrs. The reaction mixture was slowly poured into n-hexane. A powdery polymer isolated was dried at 60° C. in a vacuum oven. The copolymer yield was 68% (3.40 g) and the composition was TBMA/MFA=42/58 (mol/mol). Mₙ=16,250 and M_{w}=28,600. T_{g} was 97° C.

### Example 10

### TBFA-MMA (1:1 mol/mol in Feed)

In a round-bottomed flask, TBFA (3.01 g), MMA (2.07 g), AIBN (0.201 g), and MEK (15.0 g) were placed, and a freeze-thaw cycle was repeated a couple of times. Polymerization reaction was carried out at 60° C. for 96 hrs. The powdery polymer was isolated by precipitation into n-hexane and dried at 60° C. in a vacuum oven. The copolymer yield was 75% (3.78 g) and the composition was TBFA/MMA=45/55. Mₙ=19,800 and Mₙ=38,800. T_{g} was 94° C.

### Example 11

### TBMA-MFA (1:4 mol/mol in Feed)

TBMA (1.20 g), MFA (3.50 g), AIBN (0.188 g), and MEK (14.1 g) were placed in a round-bottomed flask and a freeze-thaw cycle was repeated a couple of times. Polymerization reaction was carried out at 60° C. for 96 hrs. The reaction mixture was slowly poured into 250 mL of n-hexane. A polymer recovered by filtration was dissolved in 30 g of acetone, which was slowly poured into 600 mL of n-hexane. The powdery polymer isolated, was dried at 60° C. in a vacuum oven. The copolymer yield was 96% (5.50 g) and the composition was TBMA/MFA=21/79 (mol/mol). Mₙ=48,200 and M_{w}=75,600.

### Example 12

### TBTFMA-MMA (3:2 mol/mol in Feed)

TBTFMA (4.00 g), MMA (1.36 g), and AIBN (0.219 g) were placed in a round-bottomed flask and a freeze-thaw cycle was repeated a couple of times. Polymerization reaction was carried out at 60° C. for 17.5 hrs. The reaction mixture was diluted with acetone and slowly poured into n-hexane. A powdery polymer isolated was dried at 60° C. in a vacuum oven. The copolymer yield was 52% (2.80 g) and the composition was TBTFMA/MMA=35/65 (mol/mol). Mₙ=28,800 and M_{w}=49,800. T_{g} was 99° C.

### Example 13

### TBMA-MFA (2:3 mol/mol in Feed)

TBMA (2.40 g), MFA (2.70 g), AIBN (0.192 g), and MEK (15.1 g) were placed in a round-bottomed flask and a freeze-thaw cycle was repeated a couple of times. Polymerization reaction was carried out at 60° C. for 65 hrs. The reaction mixture was slowly poured into n-hexane. A powdery polymer isolated was dried at 60° C. in a vacuum oven. The copolymer yield was 100% (5.10 g) and the composition was TBMA/MFA=46/54 (mol/mol). Mₙ=24,800 and M_{w}=51,900. T_{g} was 99° C.

### Example 14

### TBFA-MMA (2:3 mol/mol in Feed)

TBFA (2.40 g), MMA (2.48 g), AIBN (0.196 g), and MEK (14.6 g) were placed in a round-bottomed flask and a freeze-thaw cycle was repeated a couple of times. Polymerization reaction was carried out at 60° C. for 66 hrs. The reaction mixture was slowly poured into n-hexane. A powdery polymer isolated was dried at 60° C. in a vacuum oven. The copolymer yield was 79% (3.83 g) and the composition was TBFA/MMA=35/65 (mol/mol). Mₙ=17,300 and M_{w}=35,000. T_{g} was 88° C.

### Example 15

### TBMA-MFA (3:7 mol/mol in feed)

TBMA (3.06 g), MFA (1.81 g), AIBN (0.194 g), and MEK (14.6 g) were placed in a round-bottomed flask and a freeze-thaw cycle was repeated a couple of times. Polymerization reaction was carried out at 60° C. for 21 hrs. The reaction mixture was slowly poured into n-hexane. A powdery polymer isolated was dried at 60° C. in a vacuum oven. The copolymer yield was 99% (4.92 g) and the composition was TBMA/MFA=35/65 (mol/mol). Mₙ=39,400 and M_{w}=69,800. T_{g} was 104° C.

### Example 16

### TBMA-MFA (3:7 mol/mol in Feed)

TBMA (3.06 g), MFA (1.81 g), AIBN (0.385 g), dodecanethiol (0.083 g) and MEK (29.2 g) were placed in a round-bottomed flask and a freeze-thaw cycle was repeated a couple of times. Polymerization reaction was carried out at 60° C. for 24 hrs. The reaction mixture was slowly poured into n-hexane. A powdery polymer isolated was dried at 60° C. in a vacuum oven. The copolymer yield was 97% (4.71 g) and the composition was TBMA/MFA=35/65 (mol/mol). Mₙ=13,000 and M_{w}=19,200. T_{g} was 98° C.

### Example 17

### TBFA-MFA-MEST (1:1:1 mol/mol in feed)

A mixture of TBFA (1.4707 g), MFA (1.0477 g), MEST (2.3702 g), and AIBN (0.2643 g) was deaerated by bubbling N₂ for 30 min and heated a 60° C. in N₂ for 3 days 18 hrs. The resulting solid was dissolved in acetone and the solution was poured into hexanes. The precipitated polymer was recovered by filtration, washed with hexanes, and dried in a vacuum oven at room temperature overnight. The terpolymer yield was 60% (2.9147 g) and the composition was TBFA/MFA/MEST=26/18/56 (molar ratio). Mₙ=4,000 and M_{w}=9,100.

### Example 18

### TBFA-MFA-MEIN (1:1:2 mol/mol in Feed)

A mixture of TBFA (1.4670 g), MFA (1.0488 g), MEIN (2.6091 g), and AIBN (0.2630 g) was deaerated by bubbling N₂ for 30 min and heated at 60° C. in N₂ for 5 days and 23 hrs. The resulting solid was dissolved in acetone/ethyl acetate and the solution was slowly poured into hexanes. The precipitated terpolymer was recovered by filtration, washed with hexanes, and dried in a vacuum oven at 50° C. overnight. The yield was 37% (1.9105 g) and the composition was TBFA/MFA/MEIN=23/12/65 (molar ratio). Mₙ=4,700 and M_{w}=10,100. T_{g} was 130° C.

### Example 19

### TBMA-MFA (3:7 mol/mol in Feed)

TBMA (3.06 g), MFA (1.81 g), AIBN (0.385 g), and MEK (29.2 g) were placed in a round-bottomed flask and a freeze-thaw cycle was repeated a couple of times. Polymerization reaction was carried out at 60° C. for 24 hrs. The reaction mixture was slowly poured into n-hexane. A powdery polymer isolated was dried at 60° C. in a vacuum oven. The copolymer yield was 97% (4.71 g) and the composition was TBMA/MFA=32/68 (mol/mol). Mₙ=12,900 and M_{w}=19,200. T_{g} was 98° C.

### Example 20

### TBTFMA-MEST (1:1 mol/mol in Feed)

A mixture of TBTFMA (7.8474 g), MEST (4.7376 g), and AIBN (0.5252 g) was deaerated by bubbling N₂ for 30 min and heated at 60° C. in N₂ for 6 days 22 hours. The polymer was precipitated in methyl perfluoro-n-propyl ether, filtered, and washed with methyl perfluoro-n-propyl ether. After drying in a vacuum oven at room temperature overnight, the polymer yield amounted to 1.8629 g (15%). The copolymer composition was TBTFMA/MEST=48/52 (mol/mol). Mₙ=1,600 and M_{w}=2,200.

### Example 21

### TBTFMA-MFA (4:6 mol/mol in feed)

TBTFMA (8.80 g), MFA (7.00 g), AIBN (1.26 g), dodecanethiol (0.25 g) and MEK (96.0 g) were placed in a round-bottomed flask and a freeze-thaw cycle was repeated a couple of times. Polymerization reaction was carried out at 60° C. for 18.5 hrs. The reaction mixture was slowly poured into 500 mL of n-hexane. A polymer recovered by filtration was dissolved in 50 g of acetone, which was slowly poured into 500 mL of n-hexane. A powdery polymer was isolated and dried at 60° C. in a vacuum oven. The copolymer yield was 66% (10.4 g) and the composition was TBTFMA/MFA=29/71 (mol/mol). Mₙ=7,700 and M_{w}=15,000. T_{g} was 107° C.

### Example 22

### TBFA-METL (1:1 mol/mol in Feed)

A mixture of TBFA (2.9403 g), METL (2.8939 g), and AIBN (0.2625 g) was deaerated by bubbling N₂ for 30 minutes and then heated at 60° C. in N₂ for 138 hrs. The reaction mixture was diluted with acetone and slowly poured into hexanes. The precipitated polymer was isolated by filtration, washed with hexanes, and dried in a vacuum oven at 50° C. overnight. The copolymer yield was 4.6% (0.2696 g) and the composition was TBFA/METL=48/52 (mol/mol). Mₙ=4,900 and M_{w}=6,800.

Table 4 summarizes Examples 1-22.

TABLE 4

| | | Molar | | | |
|---|---|---|---|---|---|
| | | Ratio | Molar Ratio | | |
| Example | Monomers | (Feed) | (Analyzed) | Mₙ | M_{w} |
| 1 | TBMA/TFMEST | 1/1 | 83/17 | 3500 | 5200 |
| 2 | TBTFMA/MEST | 1/1 | 39/61 | 1400 | 1900 |
| 3 | TBMA/MEST | 1/1 | 57/43 | 8100 | 11500 |
| 4 | TBMA/MEST | 2/3 | 50/50 | 1800 | 2100 |
| 5 | TBFA/MEST | 1/1 | 47/53 | 5700 | 9300 |
| 6 | TBFA/MEIN | 1/1 | 39/61 | 6700 | 13000 |
| 7 | TBTFMA/MMA | 1/4 | 14/86 | 33900 | 75100 |
| 8 | TBMA/MMA | 1/9 | 10/90 | 39200 | 62100 |
| 9 | TBMA/MMA | 2/3 | 42/58 | 16250 | 28600 |
| 10 | TBFA/MMA | 1/1 | 45/55 | 19800 | 38800 |
| 11 | TBMA/MFA | 1/4 | 21/79 | 48200 | 75600 |
| 12 | TBTFMA/MMA | 3/2 | 35/65 | 28800 | 49800 |
| 13 | TBMA/MFA | 2/3 | 46/54 | 24800 | 51900 |
| 14 | TBFA/MMA | 2/3 | 35/65 | 17300 | 35000 |
| 15 | TBMA/MFA | 3/7 | 35/65 | 39400 | 69800 |
| 16 | TBMA/MFA | 3/7 | 35/65 | 13000 | 19200 |
| 17 | TBFA/MFA/ | 1/1/1 | 26/18/56 | 4000 | 9100 |
| | MEST | | | | |
| 18 | TBFA/MFA/ | 1/1/1 | 23/12/65 | 4700 | 10100 |
| | MEIN | | | | |
| 19 | TBMA/MFA | 3/7 | 32/68 | 12970 | 19200 |
| 20 | TBTFMA/MEST | 1/1 | 48/52 | 1600 | 2200 |
| 21 | TBTFMA/MFA | 3/7 | 29/71 | 7700 | 15000 |
| 22 | TBFA/METL | 1/1 | 48/52 | 4900 | 6800 |

In Examples 1-22, the copolymer has an acid-labile monomer (TBMA, TBTFMA, or TBFA) content of from 10 to 83 mole percent, analyzed by ¹³C-NMR. In the main chain scission experiments that follow, the selected copolymers have an acid-labile monomer content in an amount of from 39 to 83 mole percent, analyzed by ¹³C-NMR. In the dissolution kinetics experiments that follow, the selected copolymers have an acid-labile monomer content in an amount of from 32 to 47 mole percent, analyzed by ¹³C-NMR.

In Examples 1-22 employing acid stable MEST, MFA and MMA, the analyzed MEST content is from 43 to 61 mole percent in the copolymer; the analyzed MFA content is from 34 to 79 mole percent in the copolymer; and the analyzed MMA content is from 55 to 90 mole percent in the copolymer. In each case, mole percent is based on total moles of all monomers in the copolymer.

Thus, in one embodiment, the acid-stable sterically hindered monomer can be present in the copolymer in an amount of about 10 to 95 mole percent, more particularly, about 40 to about 80 mole percent, and even more particularly, 50 to 65 mole percent, based on total moles of monomer in the polymer equaling 100 mole percent. More specifically, the copolymer of the photoresist composition can consist essentially of 40 to 50 mole percent MEST, the balance being an acid-labile monomer in an amount of 60 to 50 mole percent. Further, the copolymer can consist essentially of 60 to 70 mole percent MEIN, the balance being an acid-labile monomer in an amount of 40 to 30 mole percent. Still further, the copolymer can consist essentially of 10 to 80 mole percent MFA, the balance being an acid-labile monomer in an amount of 90 to 20 mole percent. Still further, the copolymer can consist essentially of 50 to 90 mole percent MMA, the balance being an acid-labile monomer in an amount of 50 to 10 mole percent. The attainable copolymer composition is determined by monomer reactivity ratios. Incorporation of TBTFMA and MEST in the copolymer is less than 50 mole percent in general.

### Main Chain Scission by Irradiation.

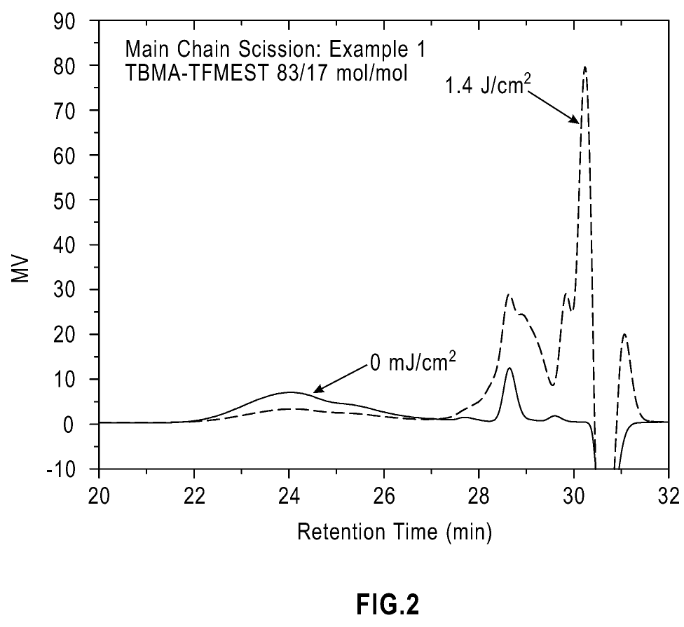

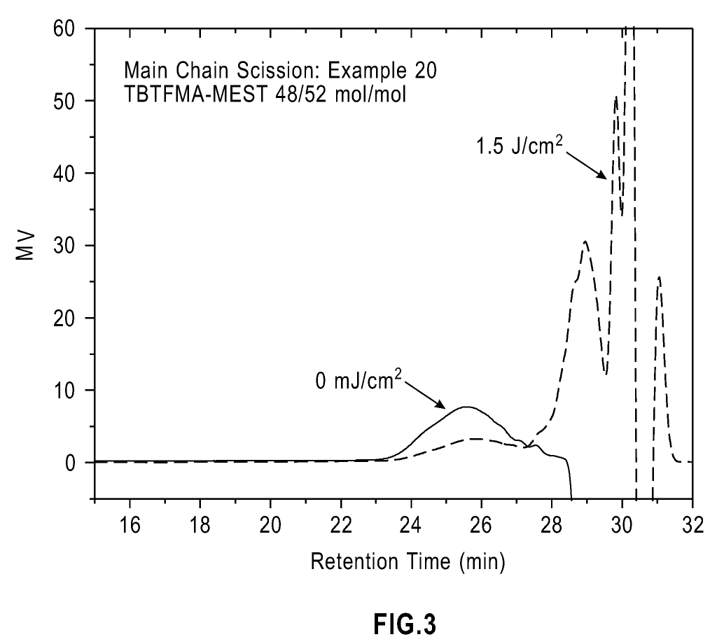

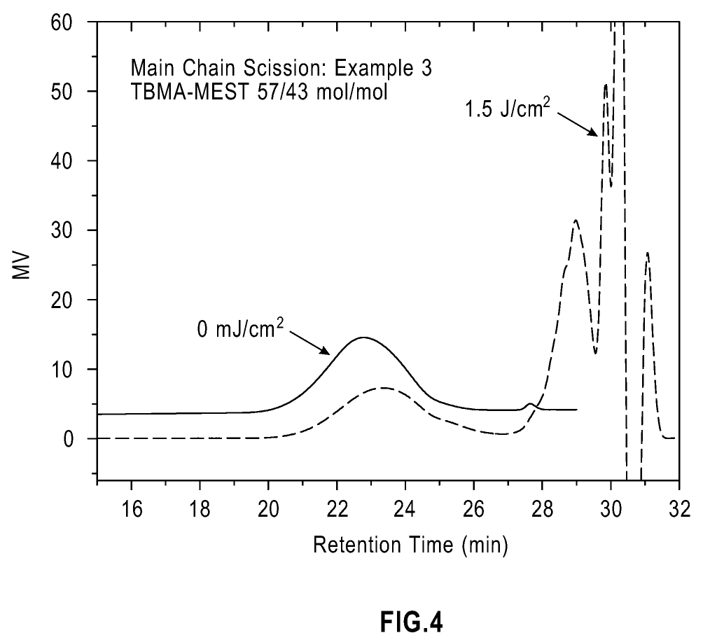

Copolymer were cast as films on 5″ Si wafers, exposed with ca. 1.5 J/cm² of 254 nm radiation, baked at 120° C. for 60 sec, and dissolved in THF into a small vial. After concentrating the solution by evaporation of the solvent at room temperature, the samples were subjected to GPC analysis. FIG. 2-4 demonstrate that the copolymers TBMA-TFMEST 83/17 (mol/mol, analyzed) of Example 1, and TBTFMA-MEST 48/52 (mol/mol, analyzed) of Example 20) and TBMA-MEST 57/43 (mol/mol, analyzed) of Example 3, each undergo chain scission to form low molecular weight peaks upon exposure to ca. 1.5 J/cm² of 254 nm radiation.

### Dissolution Kinetics.

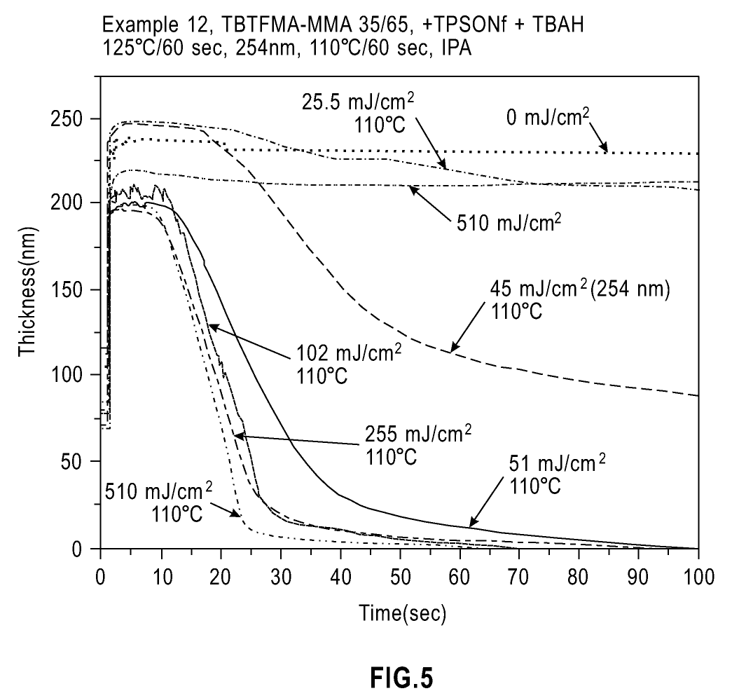

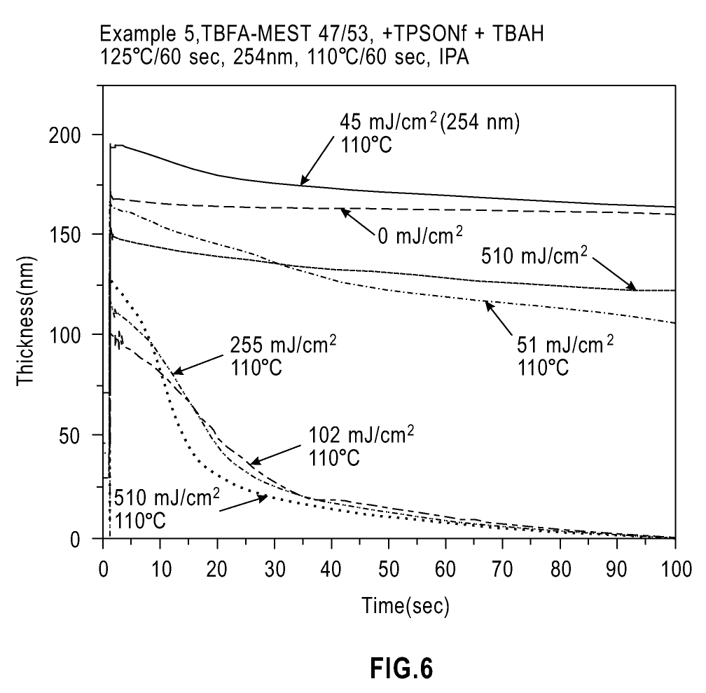

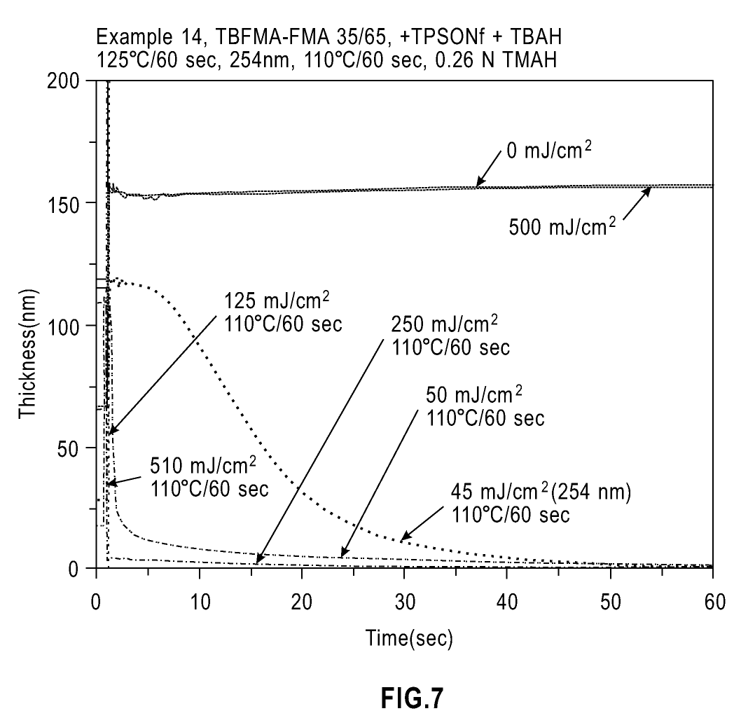

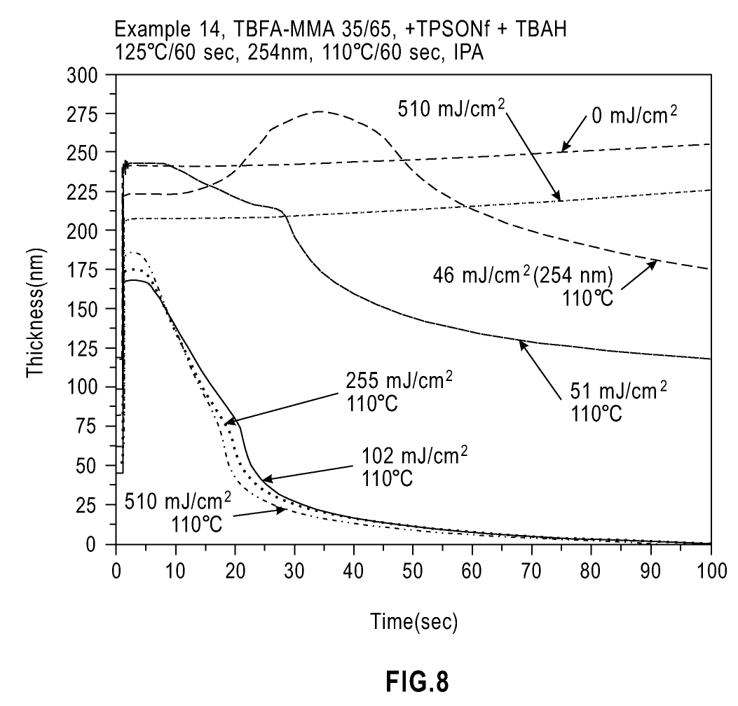

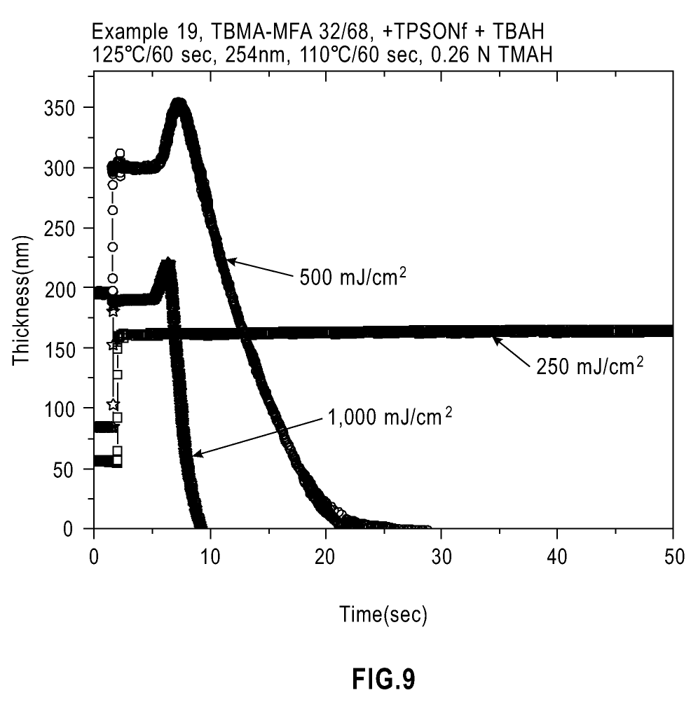

Photoresist compositions were prepared containing an above-described copolymer, a photoacid generator (PAG) triphenylsulfonium perfluorobutylsulfonate (TPSONf) (5 wt % to polymer), and tetrabutylammonium hydroxide, TBAH, (20 wt % to PAG) as a base quencher. The compositions were cast on quartz crystal discs, the resulting films were given a post-casting bake (PAB) at 125° C. for 60 sec, and then exposed to a varying dose of 254 nm radiation. The exposed films were given a post-exposure bake (PEB) at 110° C. for 60 sec, and subjected to QCM (quartz crystal microbalance) analysis in developer solvents. FIG. 5-9 illustrate the dissolution behavior copolymers TBTFMA-MMA 35165 (mol/mol, analyzed) of Example 10, TBFMA-MEST 47/53 (mol/mol, analyzed) of Example 5, TBFMA-FMA 35/65 (mol/mol, analyzed) of Example 14, TBMA-MFA 35/65 (mol/mol, analyzed) of Example 15, and TBMA-MFA 32/68 (mol/mol, analyzed) of Example 19, respectively. Without post-exposure bake (PEB), the films exposed to high dose (500 mJ/cm²) do not dissolve or only slowly dissolve in developer. At a relatively high dose of ca. 50 mJ/cm² of filtered 254 nm radiation (in comparison with a dose typically given to a chemical amplification resist) followed by PEB, the films dissolve slowly. However, exposure of the films to >100 mJ/cm² of unfiltered 254 nm radiation followed by PEB results in fast dissolution in developer due to a combined effect of radiation-induced main chain scission and acid catalyzed deprotection of t-butyl ester.

### Contrast Curves.

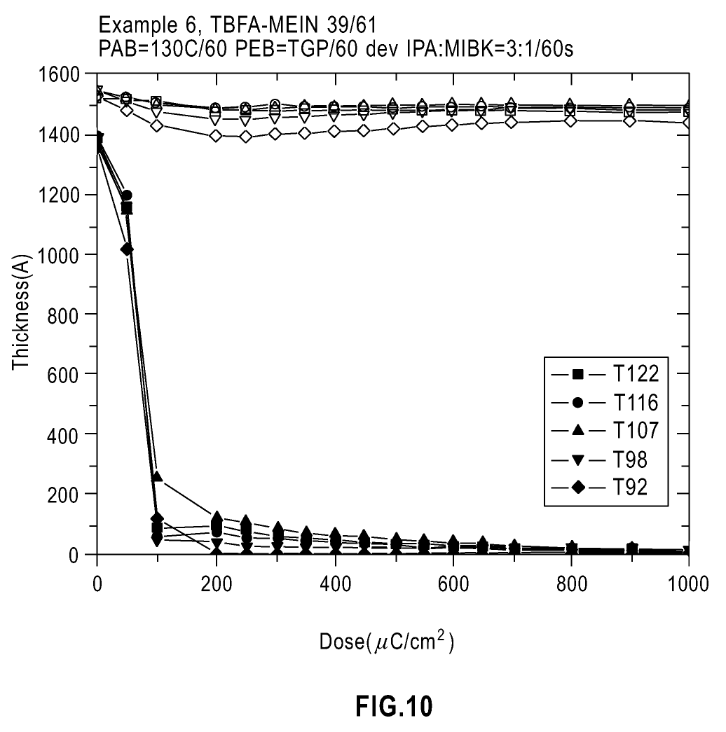

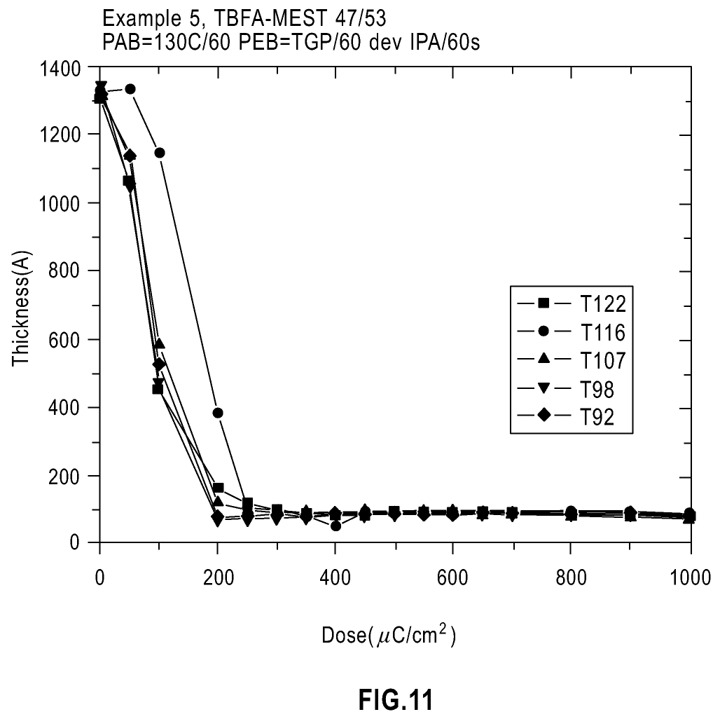

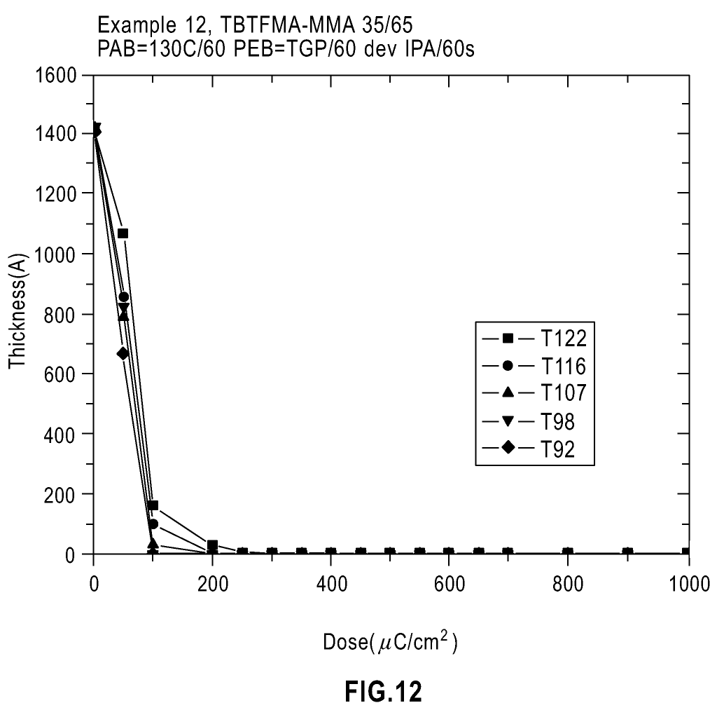

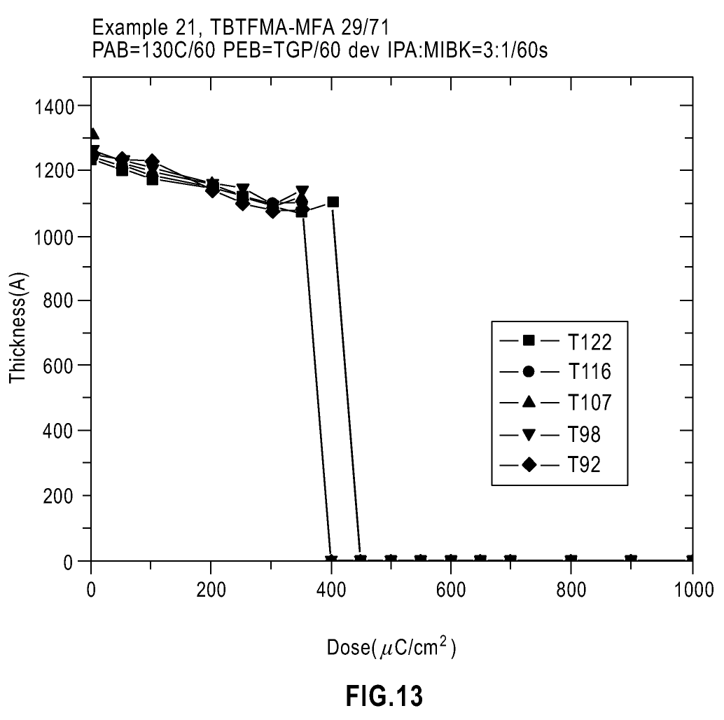

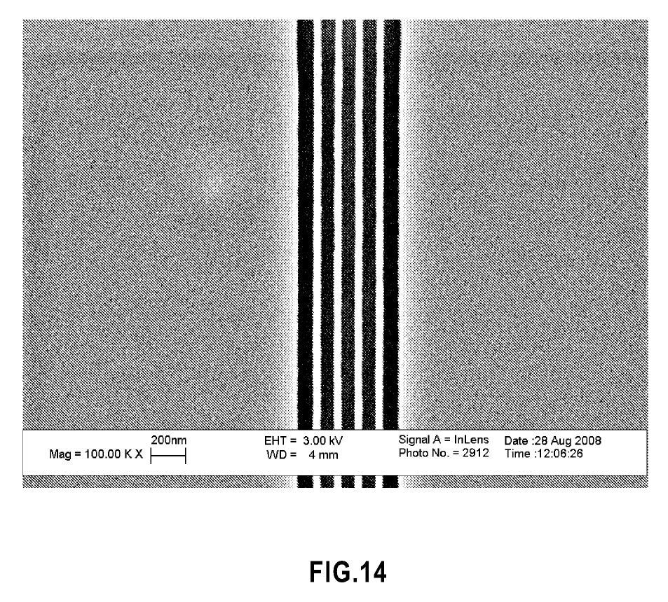

Photoresist compositions containing copolymer from the above-described Examples 1-21, TPSONf (5 wt % to polymer) and TBAH (20 wt % to PAG) were spin cast on 4-inch Si wafers. The films were given a post-apply bake (PAB) at 130° C. for 60 sec, then flood-exposed to a varying dose of e-beam radiation (Leica, 100 keV). The films were then given a post-exposure bake (PEB) at 92° C. to 122° C. for 60 sec on a thermal gradient hotplate (TGP), and developed in a specified solvent (isopropyl alcohol (IPA), methyl isobutyl ketone (MIBK), and mixtures thereof). Contrast curves are shown for the copolymer TBFA-MEIN 39/61 (mol/mol, analyzed) of Example 6, TBFA-MEST 47/53 (mol/mol, analyzed) of Example 5, TBTFMA-MMA 35/65 (mol/mol, analyzed) of Example 12, and TBTFMA-MFA 29/71 (mol/mol, analyzed) of Example 21 in FIG. 10-13. The exposed resist films dissolve rapidly in a developer when the exposure dose is 100-400 microCoulombs/cm² (μC/cm²). The PEB temperature variation does not affect the dose to clear (E₀), which is advantageous. The E₀ obtained for the disclosed copolymers is much smaller than the imaging dose for PMMA of approximately 1,200 microCoulombs/cm² on the same exposure tool. The dose can be controlled by changing the polymer composition and/or molecular weight, by adjusting the PAG and base quencher concentrations, and by changing a developer solvent. FIG. 14 is a scanning electron micrograph of 50 nm line/space patterns delineated in a photoresist composition made with TBTFMA-MMA 35/65 (mol/mol) of Example 12 by a dose of 400 microCoulombs/cm² of e-beam (50 keV) exposure, post-exposure bake, and development with isopropanol.

Based on the above results, the resist copolymers exhibit a good balance between acid catalyzed deprotection and main chain scission susceptibility when the repeating units derived from the acid-labile monomer are present in the polymer in an amount of about 10 to about 90 mole percent, more particularly 20 to 70 mole percent, and even more particularly 30 to 50 mole percent, based on total moles of monomer in the polymer equaling 100 percent.

The singular forms “a,” “an,” and “the” include plural referents unless the context clearly dictates otherwise. The endpoints of all ranges directed to the same characteristic or component are independently combinable and inclusive of the recited endpoint.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A photoresist composition, comprising:
a polymer capable of radiation induced main chain scission and acid-catalyzed deprotection, wherein the polymer is derived by free radical polymerization of two or more monomers, each monomer having a non-hydrogen alpha-substituent on a polymerizable vinyl group; and
a photochemical acid generator.

2. The photoresist composition of claim 1, further comprising a base quencher and a solvent.

3. The photoresist composition of claim 1, wherein the two or more monomers are selected from the group consisting of alpha-substituted acrylates, alpha-substituted styrenes, and combinations thereof, wherein at least one monomer comprises an acid-labile protecting group.

4. The photoresist composition of claim 3, wherein the alpha-substituted acrylate monomer has the formula (1) 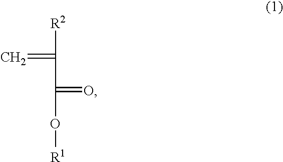
wherein
R¹ is selected from the group consisting of hydrogen, fluorinated alkyl, methyl, ethyl, propyl, iso-propyl, n-butyl, 2-ethylhexyl, phenyl, substituted phenyl, t-butyl, adamantyl, norbornyl, isobornyl, 2-methyl-2-adamantyl, 2-methyl-2-isobornyl, 2-methyl-2-tetracyclododecenyl, 2-methyl-2-dihydrodicyclopentadienyl-cyclohexyl, 1-methylcyclopentyl, 1-methylcyclohexyl, alkylcyclooctyl, dimethylbenzyl, and tetrahydropyranyl; and
R² is selected from the group consisting of fluorine, chlorine, iodine, methyl, fluoromethyl, difluoromethyl, and trifluoromethyl.

5. The photoresist composition of claim 3, wherein the alpha-substituted styrene monomer has the formula (2) 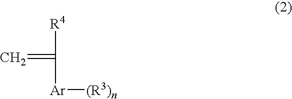
wherein
n is an integer from zero to 5;
R³ is selected from the group consisting of hydrogen, alkyl, fluorinated alkyl, hydroxyl, alkoxy, fluorinated alkoxy, halogen, cyano, —OCOOC(CH₃)₃, —OCH₂COOC(CH₃)₃, and —O-tetrahydropyranyl; and
R⁴ is selected from the group consisting of fluorine, chlorine, methyl, fluoromethyl, difluoromethyl, and trifluoromethyl.

6. The photoresist composition of claim 5, wherein R³ and R⁴, taken together, form a five-member or six-member alicyclic or heterocyclic ring that is fused to the Ar group.

7. The photoresist composition of claim 3, wherein the at least one monomer comprising an acid-labile group is present in the polymer in an amount of from about 10 to about 90 mole percent, based on total moles of monomer in the polymer.

8. The photoresist composition of claim 3, wherein the alpha-substituted acrylate is selected from the group consisting of TBMA, TBTFMA, TBFA, MMA, MFA and combinations thereof.

9. The photoresist composition of claim 3, wherein the alpha-substituted styrene is selected from the group consisting of MEST, TFMEST, MEIN, METL and combinations thereof.

10. The photoresist composition of claim 3, wherein the polymer consists essentially of two different alpha-substituted acrylate units, one of which bears an acid-labile protecting group.

11. The photoresist composition of claim 3, wherein the polymer consists essentially of an alpha-substituted acrylate unit and an alpha-substituted styrene unit, wherein the alpha-substituted acrylate unit bears an acid-labile protecting group.

12. The photoresist composition of claim 3, wherein the polymer consists essentially of an alpha-substituted acrylate unit and an alpha-substituted styrene unit, wherein the alpha-substituted styrene unit bears an acid-labile protecting group.

13. The photoresist composition of claim 1, wherein the polymer is selected from the group consisting of: TBFA-MEIN copolymer, TBFA-MEST copolymer; TBFA-MFA-MEIN terpolymer; TBFA-MFA-MEST terpolymer; TBFA-MMA copolymer; TBFA-METL copolymer; TBMA-MEST copolymer; TBMA-MFA copolymer; TBMA-MMA copolymer; TBMA-TFMEST copolymer; TBMA-METL copolymer; TBTFMA-MEST copolymer; TBTFMA-MMA copolymer; TBTFMA-MEST copolymer; TBTFMA-METL copolymer; and TBTFMA-MFA copolymer.

14. A method of forming a positive relief image, comprising:
disposing on a substrate a layer comprising a polymer capable of radiation induced main chain scission and acid-catalyzed deprotection, wherein the polymer is derived by free radical polymerization of two or more monomers, each having a non-hydrogen alpha-substituent on a polymerizable vinyl group; and a photo-acid generator;
imagewise irradiating the layer to form fragmented chains of the polymer in an irradiated area;
heating the layer to effect acid-catalyzed deprotection of the fragmented chains of polymer in the irradiated area; and
developing the layer with a developer to form the positive relief image disposed on the substrate.

15. The method of claim 14, wherein the developing is performed with an organic solvent, an aqueous base, or a combination thereof.

16. The method of claim 14, wherein the imagewise irradiation is deep ultraviolet, EUV, x-ray, or electron beam radiation.

17. The method of claim 14, wherein the method further comprises transferring the relief image to the substrate by means of a substrate etchant, wherein the relief image provides selective contact between the substrate and the substrate etchant.

18. The method of claim 14, wherein the substrate is selected from the group consisting of a semiconductor, a ceramic, and a metal.

19. The method of claim 14, wherein the substrate is selected from the group consisting of quartz, Cr-coated quartz, Cr-coated glass, silicon dioxide, silicon nitride, and silicon oxynitride.

20. The method of claim 14, wherein the polymer consists essentially of two or more monomers selected from the group consisting of alpha-substituted acrylates, alpha-substituted styrenes, and combinations thereof, wherein at least one monomer comprises an acid-labile protecting group.

21. The method of claim 14, wherein the layer further comprises a base quencher.

22. The method of claim 14, wherein the polymer is selected from the group consisting of: TBFA-MEIN copolymer, TBFA-MEST copolymer; TBFA-MFA-MEIN terpolymer; TBFA-MFA-MEST terpolymer; TBFA-MMA copolymer; TBFA-METL copolymer; TBMA-MEST copolymer; TBMA-MFA copolymer; TBMA-MMA copolymer; TBMA-TFMEST copolymer; TBMA-METL copolymer; TBTFMA-MEST copolymer; TBTFMA-MMA copolymer; TBTFMA-MEST copolymer; TBTFMA-METL copolymer; and TBTFMA-MFA copolymer.
